(19) United States
(12) Patent Application Publication
(10) Pub. No.: US 2026/0190764 A1
(43) Pub. Date: Jul. 2, 2026

(54) DISPLAY DEVICE AND METHOD OF MANUFACTURING THE SAME

(71) Applicant: Samsung Display Co., Ltd., Yongin-si (KR)

(72) Inventors: Jong Hyeon CHOI, Yongin-si (KR); Jeong Ho HWANG, Yongin-si (KR)

(21) Appl. No.: 19/305,603

(22) Filed: Aug. 20, 2025

(30) Foreign Application Priority Data
Dec. 31, 2024 (KR) 10-2024-0201794

(51) Int. Cl. H10K 59/80; H10K 59/12; H10K 59/38

(52) U.S. Cl. CPC H10K 59/871; H10K 59/1201; H10K 59/38; H10K 59/8791

(57) ABSTRACT

A display device includes: a substrate including a display area and a non-display area; a light emitting element layer on the substrate, overlapping the display area, and including a light emitting element; a color filter layer on the light emitting element layer and overlapping the light emitting element layer; an overcoat layer on the color filter layer; a buffer layer directly on the overcoat layer; and an optical member directly on the buffer layer, wherein the buffer layer includes a first portion overlapping the optical member and a second portion that does not overlap the optical member and is outside the first portion, the buffer layer includes a first surface facing the overcoat layer and a second surface opposite to the first surface, and the second surface of the second portion of the buffer layer includes a curved surface.

### CROSS-REFERENCE TO RELATED APPLICATION

The present application claims priority to and the benefit of Korean Patent Application No. 10-2024-0201794, filed on Dec. 31, 2024, in the Korean Intellectual Property Office, the entire disclosure of which is incorporated herein by reference.

### BACKGROUND

### 1. Field

Aspects of some embodiments of the present disclosure relate to a display device and a method of manufacturing the same.

### 2. Description of the Related Art

As an information society develops, consumer demand for display devices for displaying images is increasing in various forms. For example, the display device has been applied to various electronic devices such as smartphones, digital cameras, laptop computers, navigation devices, and smart televisions.

Display devices may include flat panel display devices such as liquid crystal display devices, field emission display devices, or light emitting display devices. Light emitting display devices include organic light emitting display devices including organic light emitting elements, inorganic light emitting display devices including inorganic light emitting elements such as an inorganic semiconductor, and subminiature light emitting display devices including micro light emitting elements.

Organic light emitting elements may include two opposing electrodes and a light emitting layer interposed therebetween. The light emitting layer may receive electrons and holes from the two electrodes and recombines the electronic and the holes to generate excitons, and the generated excitons change from an excited state to a ground state, thereby emitting light.

Organic light emitting display devices including the organic light emitting element may be configured in a light weight and thin shape with low power consumption because of not requiring a light source such as a backlight unit, and has also attracted attention as a next-generation display device because of having high-quality characteristics such as a relatively wide viewing angle, relatively high luminance and contrast, and a relatively fast response speed.

The above information disclosed in this Background section is only for enhancement of understanding of the background and therefore the information discussed in this Background section does not necessarily constitute prior art.

### SUMMARY

Aspects of some embodiments of the present disclosure include a display device that may be capable of relatively improving display quality and reliability.

Aspects of some embodiments of the present disclosure include a method of manufacturing a display device that may be capable of relatively improving display quality and reliability.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device comprises a substrate including a display area and a non-display area; a light emitting element layer positioned on the substrate, overlapping the display area, and including a light emitting element; a color filter layer positioned on the light emitting element layer and overlapping the light emitting element layer; an overcoat layer positioned on the color filter layer; a buffer layer positioned directly on the overcoat layer; and an optical member positioned directly on the buffer layer, wherein the buffer layer includes a first portion overlapping the optical member and a second portion that does not overlap the optical member and is positioned outside the first portion, the buffer layer includes a first surface facing the overcoat layer and a second surface opposite to the first surface, and the second surface of the second portion of the buffer layer includes a curved surface.

According to some embodiments, the optical member includes an optical substrate positioned on the buffer layer and an optical functional layer positioned on the optical substrate, and the optical substrate is in direct contact with the buffer layer.

According to some embodiments, the optical functional layer is not in direct contact with the buffer layer.

According to some embodiments, the second portion of the buffer layer is in further contact with the outermost side surface of the optical substrate.

According to some embodiments, the display device further comprises an adhesive residual pattern positioned between the optical substrate and the buffer layer, wherein the buffer layer is in direct contact with the adhesive residual pattern.

According to some embodiments, the outermost edge of the buffer layer is positioned inward relative to the outermost side surface of the overcoat layer.

According to some embodiments of the present disclosure, a display device comprises a substrate including a display area and a non-display area; a light emitting element layer positioned on the substrate, overlapping the display area, and including a light emitting element; a color filter layer positioned on the light emitting element layer and overlapping the light emitting element layer; an overcoat layer positioned on the color filter layer; a buffer layer positioned directly on the overcoat layer; and an optical member positioned directly on the buffer layer, wherein the buffer layer includes a first portion overlapping the optical member and a second portion that does not overlap the optical member and is positioned outside the first portion, and a surface curing rate of the first portion of the buffer layer and a surface curing rate of the second portion of the buffer layer are different from each other.

According to some embodiments, the surface curing rate of the first portion of the buffer layer is greater than the surface curing rate of the second portion of the buffer layer.

According to some embodiments of the present disclosure, a display device comprises a substrate including a display area and a non-display area; a light emitting element layer positioned on the substrate, overlapping the display area, and including a light emitting element; a color filter layer positioned on the light emitting element layer and overlapping the light emitting element layer; an overcoat layer positioned on the color filter layer; a buffer layer positioned directly on the overcoat layer; and an optical member positioned directly on the buffer layer, wherein the buffer layer includes a first buffer layer positioned directly on the overcoat layer and a second buffer layer positioned between the first buffer layer and the optical member, and a Young's modulus of the first buffer layer and a Young's modulus of the second buffer layer are different from each other.

According to some embodiments, the Young's modulus of the first buffer layer is greater than the Young's modulus of the second buffer layer.

According to some embodiments, the Young's modulus of the first buffer layer is 100 MPa or less, and the Young's modulus of the second buffer layer is 700 MPa to 800 MPa.

According to some embodiments, the optical member includes an optical substrate and an optical functional layer positioned on the optical substrate, and the optical substrate is in direct contact with the second buffer layer.

According to some embodiments, the display device further comprises an adhesive residual pattern positioned between the optical substrate and the second buffer layer, wherein the second buffer layer is in direct contact with the adhesive residual pattern.

According to some embodiments of the present disclosure, a display device comprises a substrate including a display area and a non-display area; a light emitting element layer positioned on the substrate, overlapping the display area, and including a light emitting element; a color filter layer positioned on the light emitting element layer and overlapping the light emitting element layer; an overcoat layer positioned on the color filter layer; a buffer layer positioned directly on the overcoat layer; and an optical member positioned directly on the buffer layer, wherein the buffer layer includes a first portion overlapping the optical member and a second portion that does not overlap the optical member and is positioned outside the first portion, the buffer layer includes a first buffer layer positioned directly on the overcoat layer and a second buffer layer positioned between the first buffer layer and the optical member, and a surface curing rate of the first portion of the second buffer layer and a surface curing rate of the second portion of the second buffer layer are different from each other.

According to some embodiments, the surface curing rate of the first portion of the second buffer layer is greater than the surface curing rate of the second portion of second the buffer layer.

According to some embodiments, the optical member includes an optical substrate and an optical functional layer positioned on the optical substrate, and the optical substrate is in direct contact with the second buffer layer.

According to some embodiments, the second portion of the second buffer layer is in further contact with the outermost side surface of the optical substrate.

According to some embodiments, the outermost edge of the buffer layer is positioned inward relative to the outermost side surface of the overcoat layer.

According to some embodiments of the present disclosure, an electronic device including a display device, comprises a substrate including a display area and a non-display area; a light emitting element layer positioned on the substrate, overlapping the display area, and including a light emitting element; a color filter layer positioned on the light emitting element layer and overlapping the light emitting element layer; an overcoat layer positioned on the color filter layer; a buffer layer positioned directly on the overcoat layer; and an optical member positioned directly on the buffer layer, the buffer layer includes a first portion overlapping the optical member and a second portion that does not overlap the optical member and is positioned outside the first portion, and a surface curing rate of the first portion of the buffer layer and a surface curing rate of the second portion of the buffer layer are different from each other.

According to an aspect of the present disclosure, an electronic device including a display device, comprises a substrate including a display area and a non-display area; a light emitting element layer positioned on the substrate, overlapping the display area, and including a light emitting element; a color filter layer positioned on the light emitting element layer and overlapping the light emitting element layer; an overcoat layer positioned on the color filter layer; a buffer layer positioned directly on the overcoat layer; and an optical member positioned directly on the buffer layer, the buffer layer includes a first portion overlapping the optical member and a second portion that does not overlap the optical member and is positioned outside the first portion, the buffer layer includes a first buffer layer positioned directly on the overcoat layer and a second buffer layer positioned between the first buffer layer and the optical member, and a surface curing rate of the first portion of the second buffer layer and a surface curing rate of the second portion of the second buffer layer are different from each other.

According to some embodiments, a display device having relatively improved display quality and relatively improved reliability may be provided.

According to some embodiments, a method of manufacturing a display device that may relatively improve display quality and reliability of the display device may be provided.

However, the effects of the embodiments are not restricted to the one set forth herein. The above and other effects of the embodiments will become more apparent to one of daily skill in the art to which the embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a schematic perspective view of a display device according to some embodiments;

FIG. 2 is a cross-sectional view of the display device 10 of FIG. 1 taken along the line X1-X1′;

FIG. 3 is an enlarged plan view of portion B1 of FIG. 2;

FIGS. 4 to 10 are cross-sectional views illustrating modified examples of the display device, which are enlarged views of portion B1 of FIG. 2;

FIG. 11 is a plan view illustrating a display device of a display structure DU according to some embodiments;

FIG. 12 is an enlarged plan view of portion B3 of FIG. 11;

FIG. 13 is a cross-sectional view taken along the line X3-X3′ of FIG. 12;

FIG. 14 is a cross-sectional view of a display device 10′ according to some embodiments of FIG. 1 taken along the line X1-X1′;

FIG. 15 is an enlarged cross-sectional view of area B5 of FIG. 14;

FIGS. 16 to 34 are cross-sectional views illustrating modified examples of the display device, which are enlarged views of portion B5 of FIG. 14;

FIG. 35 is a flowchart illustrating aspects of a method of manufacturing a display device according to some embodiments;

FIG. 36 is a plan view of a first optical structure OS1;

FIG. 37 is a cross-sectional view of the first optical structure OS1 of FIG. 36 taken along the line X5-X5′;

FIG. 38 is an enlarged cross-sectional view of portion B7 of FIG. 37;

FIG. 39 is a cross-sectional view for describing an operation (S10) of preparing a second optical structure OS2;

FIG. 40 is an enlarged cross-sectional view of portion B9 of FIG. 39;

FIG. 41 is a cross-sectional view illustrating a modified example of the second optical structure OS2, which is an enlarged view of portion B9 of FIG. 39;

FIG. 42 is a view for describing an operation of adsorbing the second optical structure OS2 to a lower stage UDS;

FIG. 43 is a plan view of an upper stage UPS for describing the upper stage UPS;

FIG. 44 is a view for describing an operation of adsorbing an upper surface of a second protective film PF2 of the second optical structure OS2 to the upper stage UPS;

FIG. 45 is a view for describing an operation of detaching the lower stage UDS adsorbed to an optical substrate OPL1 of a second structure OS2;

FIG. 46 is a view for describing an operation (S30) of applying a buffer layer resin CR on an overcoat layer OC of the display structure DU;

FIG. 47 is an enlarged cross-sectional view of area B11 illustrated in FIG. 46;

FIG. 48 is a view for describing an operation (S50) of pressing the second optical structure OS2 onto the buffer layer resin CR;

FIG. 49 is a view for describing an operation (S70) of curing the buffer layer resin CR;

FIG. 50 is a view for describing an operation of detaching the upper stage UPS;

FIG. 51 is a view for describing an operation of peeling off the second protective film PF2 of the second structure OS2;

FIGS. 52 and 53 are views for describing operations of applying a first buffer layer resin CR1 and a second buffer layer resin CR2 in the method of manufacturing the display device 10′ illustrated in FIG. 14;

FIG. 54 is a block diagram of an electronic device according to some embodiments; and

FIG. 55 illustrates schematic diagrams of electronic devices according to some embodiments.

### DETAILED DESCRIPTION

Aspects of some embodiments of the present disclosure will now be described more fully hereinafter with reference to the accompanying drawings, in which aspects of some embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, aspects of some embodiments will be described in more detail with reference to the accompanying drawings.

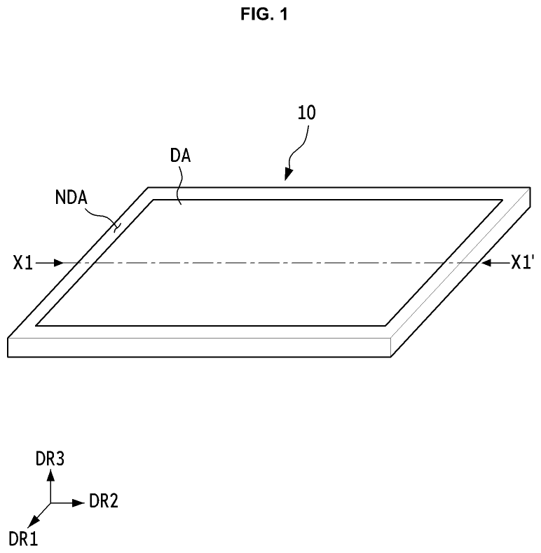

FIG. 1 is a schematic perspective view of a display device according to some embodiments.

Referring to FIG. 1, a display device 10 according to some embodiments displays a moving image or a still image. The display device 10 may refer to any display device that provides a display screen. For example, the display device 10 according to some embodiments may be applied to a display unit of a television, a laptop computer, a monitor, a billboard, or the Internet of Things (IoT).

The display device 10 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro or nano LED). Hereinafter, it is mainly described that the display device 10 is the organic light emitting display device, but the present disclosure is not limited thereto.

A shape of the display device 10 may be variously changed. For example, the display device 10 may have a shape such as a rectangle with a long width, a rectangle with a long length, a square, a quadrangle with rounded corners (vertices), other polygons, or a circle. In FIG. 1, the display device 10 having a rectangular shape with a long length in a second direction DR2 is illustrated.

The display device 10 may include a display area DA and a non-display area NDA. The display area DA is an area in which a screen may be displayed, and the non-display area NDA is an area in which a screen is not displayed. The display area DA may be located in the center of the display device 10, and the non-display area NDA may be located outside (e.g., in a periphery, surrounding, or outside a footprint of) the display area DA.

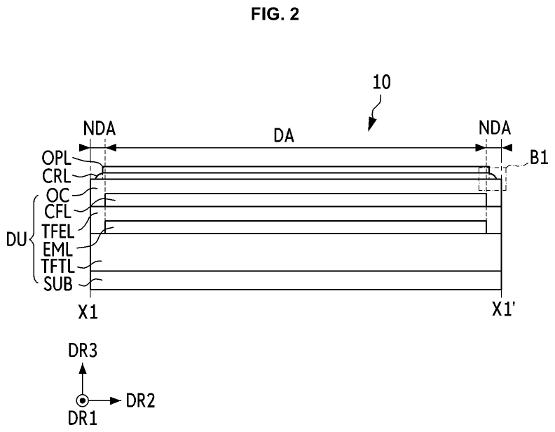

FIG. 2 is a cross-sectional view of the display device 10 of FIG. 1 taken along the line X1-X1′.

Referring to FIG. 2, the display device 10 may include a display structure DU, a buffer layer CRL positioned on the display structure DU, and an optical member OPL positioned on the buffer layer CRL. The display structure DU may include a substrate SUB, a thin film transistor layer TFTL positioned on the substrate SUB, a light emitting element layer EML positioned on the thin film transistor layer TFTL, an encapsulation layer TFEL positioned on the light emitting element layer EML, a color filter layer CFL positioned on the encapsulation layer TFEL, and an overcoat layer OC positioned on the color filter layer CFL.

The substrate SUB may be a base member that supports the layers of the display device 10. In some embodiments, the substrate SUB may be a rigid substrate and may include a glass material or a metal material. Alternatively, according to some embodiments, the substrate SUB may be a flexible substrate capable of being bent, folded, rolled, etc., and may include a polymer resin such as polyimide (PI), but is not limited thereto.

The thin film transistor layer TFTL may be positioned on the substrate SUB. The thin film transistor layer TFTL may include a plurality of thin film transistors constituting a pixel circuit of pixels. The thin film transistor layer TFTL may be positioned in the display area DA and the non-display area NDA.

The light emitting element layer EML may be positioned on the thin film transistor layer TFTL. The light emitting element layer EML including an anode, a cathode, and a light emitting layer may include a plurality of light emitting elements that emit light and a pixel defining film that defines the pixels. The plurality of light emitting elements of the light emitting element layer EML may be positioned in the display area DA.

The encapsulation layer TFEL may be positioned in the display area DA and the non-display area NDA. The encapsulation layer TFEL may cover an upper surface of the light emitting element layer EML in the display area DA. The encapsulation layer TFEL may cover a side surface of the light emitting element layer and an upper surface of the thin film transistor layer TFTL in the non-display area NDA. The encapsulation layer TFEL may include at least one inorganic film and at least one organic film for encapsulating the light emitting element layer EML.

The color filter layer CFL may be positioned on the encapsulation layer TFEL. The color filter layer CFL may be located on the encapsulation layer TFEL to overlap the light emitting element layer EML. The color filter layer CFL may include a light blocking layer and a plurality of color filters corresponding to each of the plurality of light emitting areas. Each of the color filters may selectively transmit light of a specific wavelength and block or absorb light of a different wavelength. The light blocking layer may prevent or reduce color mixing between the pixels by blocking the light from the light emitting element. The plurality of color filters of the color filter layer CFL may be positioned in the display area DA.

The overcoat layer OC may be positioned in the display area DA and the non-display area NDA. The overcoat layer OC may cover an upper surface of the color filter layer CFL in the display area DA, and may cover a side surface of the color filter layer CFL and an upper surface of the encapsulation layer TFEL in the non-display area NDA. The overcoat layer OC may planarize steps of the color filter layer CFL and protect the color filter layer CFL.

The buffer layer CRL may be positioned on the display structure DU. The buffer layer CRL may be positioned in the display area DA and the non-display area NDA. The buffer layer CRL may be positioned directly on the overcoat layer OC of the display structure DU in the display area DA and the non-display area NDA.

The buffer layer CRL may protect the layers of the display structure DU of the display device 10 from shock transmitted from the outside. The buffer layer CRL may protect the layers of the display structure DU of the display device 10 from the shock transmitted from the outside and relatively reduce the possibility of the display device 10 being damaged by the shock transmitted from the outside, thereby relatively improving reliability of the display device 10. According to some embodiments, the buffer layer CRL may have physical properties that mitigate the shock transmitted from the outside. According to some embodiments, the buffer layer CRL may have a specific range of Young's modulus values. According to some embodiments, the buffer layer CRL may have a Young's modulus value of 700 MPa to 800 MPa.

The buffer layer CRL may include an organic material. In some embodiments, the buffer layer CRL may include an insulating material, such as a polymeric resin. According to some embodiments, the buffer layer CRL may include a photocurable resin. According to some embodiments, the buffer layer CRL may include an ultraviolet (UV)-curable urethane acrylate resin.

The optical member OPL may be positioned on the buffer layer CRL. The optical member OPL may be positioned directly on the buffer layer CRL without a separate adhesive layer between the optical member OPL and the buffer layer CRL. As the optical member OPL is positioned directly on the buffer layer CRL without a separate adhesive layer, a display quality of the display device 10 may be relatively improved. The optical member OPL may be positioned in the display area DA. In addition, the optical member OPL may be further positioned in the non-display area NDA. According to some embodiments, the optical member OPL may be positioned directly on the buffer layer CRL in the display area DA and the non-display area NDA. The optical member OPL may be for relatively improving optical characteristics of the display device and may include a light-transmitting material.

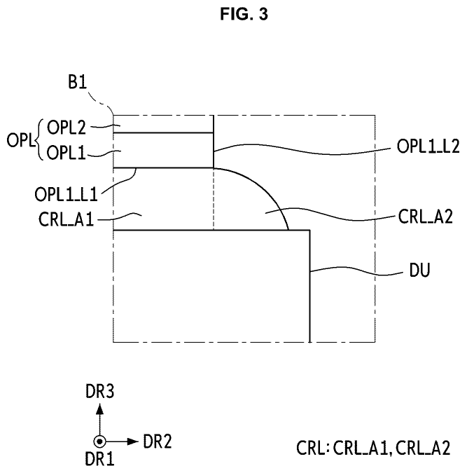

FIG. 3 is an enlarged plan view of portion B1 of FIG. 2.

Referring to FIGS. 2 and 3, the optical member OPL may include an optical substrate OPL1 and an optical functional layer OPL2 positioned on the optical substrate OPL1.

The optical substrate OPL1 may be positioned directly on the buffer layer CRL. The optical substrate OPL1 may be a substrate for forming the optical functional layer OPL2. The optical substrate OPL1 may include a light-transmitting material such as glass, polyethylene terephthalate (PET), polyimide (PI), polyamide (PA), etc.

The optical functional layer OPL2 may be located on the optical substrate OPL1. In some embodiments, the optical functional layer OPL2 may be an anti-glare layer. In some embodiments, the optical functional layer OPL2 may diffusely reflect light transmitted from the outside. In some embodiments, the optical functional layer OPL2 has uneven surfaces formed or particles added on the inside, so that external light may be scattered on the uneven surfaces or the particle surfaces. In some embodiments, the optical functional layer OPL2 may further include an anti-reflection layer, an anti-fingerprint layer, etc.

For example, the buffer layer CRL may include a first portion CRL_A1 overlapping the optical member OPL and a second portion CRL_A2 that does not overlap the optical member OPL and is positioned outside the first portion CRL_A1.

The first portion CRL_A1 of the buffer layer may be positioned in the display area DA and may be further positioned in the non-display area NDA. Only the first portion CRL_A1 of the buffer layer may overlap the optical member OPL in the display area DA and the non-display area NDA.

Hereinafter, a surface of the optical substrate OPL1 facing the buffer layer CRL is referred to as a first surface OPL1_L1 of the optical substrate OPL1, and the outermost side surface of the optical substrate OPL1 is referred to as a second surface of the optical substrate OPL1_L2.

A surface opposite to a surface of the first portion CRL_A1 of the buffer layer facing the overcoat layer OC may be in direct contact with a first surface OPL1_L1 of the optical substrate included in the optical member OPL. The surface opposite to the surface of the first portion CRL_A1 of the buffer layer facing the overcoat layer OC may be planarized to correspond to a flat shape of the first surface OPL1_L1 of the optical substrate. As the surface opposite to the surface of the first portion CRL_A1 of the buffer layer facing the overcoat layer OC is planarized by the first surface OPL1_L1 of the optical substrate, a surface quality of the display device 10 may be relatively improved, and a display quality of the display device 10 may be relatively improved.

The second portion CRL_A2 of the buffer layer may only be positioned in the non-display area NDA. A surface opposite to a surface of the second portion CRL_A2 of the buffer layer facing the overcoat layer may include a curved surface. The outermost edge of the second portion CRL_A2 of the buffer layer may be positioned inward relative to the outermost side surface of the overcoat layer OC. In some embodiments, the outermost edge of the second portion CRL_A2 of the buffer layer may coincide with the outermost side surface of the overcoat layer OC.

The first portion CRL_A1 of the buffer layer and the second portion CRL_A2 of the buffer layer may have different physical properties. In some embodiments, the first portion CRL_A1 of the buffer layer and the second portion CRL_A2 of the buffer layer may have different surface curing rates. In some embodiments, the first portion CRL_A1 of the buffer layer may have a higher surface curing rate than the second portion CRL_A2 of the buffer layer.

When a displacement from a surface of the buffer layer CRL facing the overcoat layer OC to the top of a surface opposite to the surface of the buffer layer CRL facing the overcoat layer OC is referred to as a height of the buffer layer CRL, a height of the first portion CRL_A1 of the buffer layer and a height of the second portion CRL_A2 of the buffer layer may be different from each other. According to some embodiments, the height of the second portion CRL_A2 of the buffer layer may be greater than the height of the first portion CRL_A1 of the buffer layer. According to some embodiments, the height of the first portion CRL_A1 of the buffer layer may be equal to the height of the second portion CRL_A2 of the buffer layer.

Referring to FIG. 3, the height of the first portion CRL_A1 of the buffer layer may coincide with the height of the second portion CRL_A2 of the buffer layer, and the outermost edge of the second portion CRL_A2 of the buffer layer may be positioned inward relative to the outermost side surface of the overcoat layer OC.

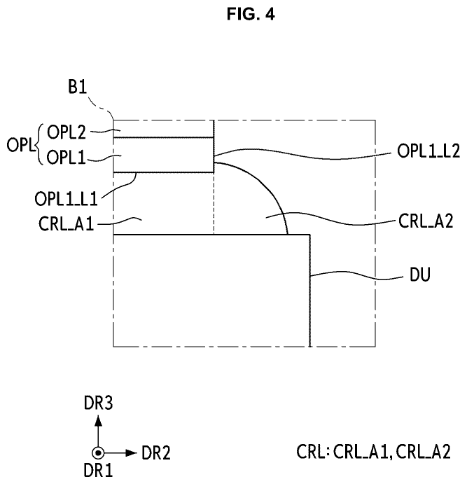

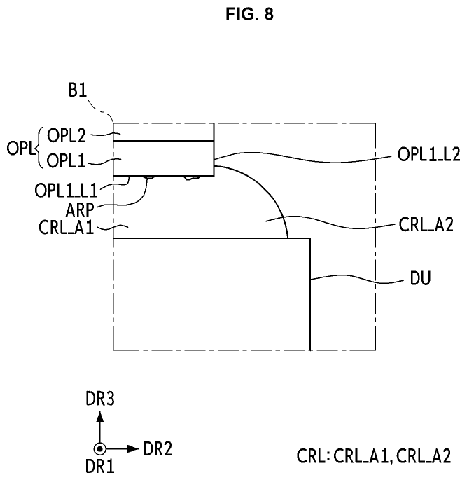

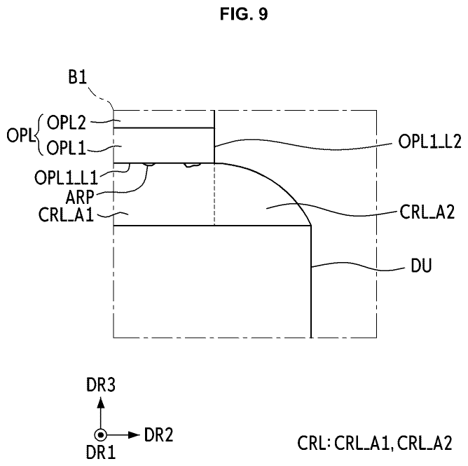

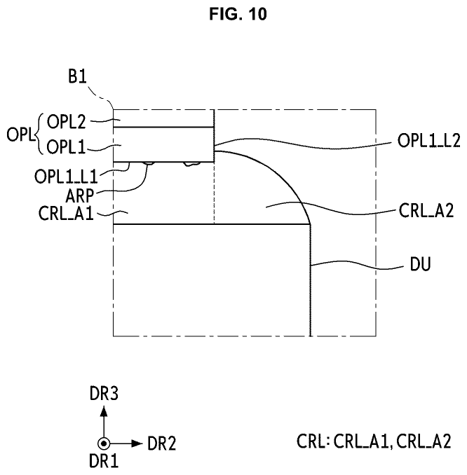

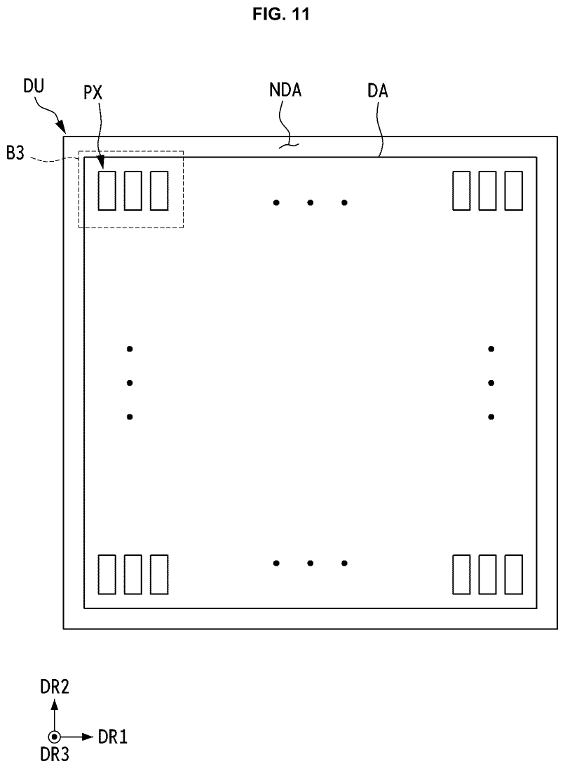

FIGS. 4 to 10 are cross-sectional views illustrating modified examples of the display device, which are enlarged views of portion B1 of FIG. 2. Hereinafter, the differences will be mainly described and duplicated descriptions will be omitted.

Referring to FIG. 4, compared to FIG. 3, the height of the second portion CRL_A2 of the buffer layer may be greater than the height of the first portion CRL_A1 of the buffer layer, and the second portion CRL_A2 of the buffer layer may be in contact with the second surface OPL_L2 of the optical substrate.

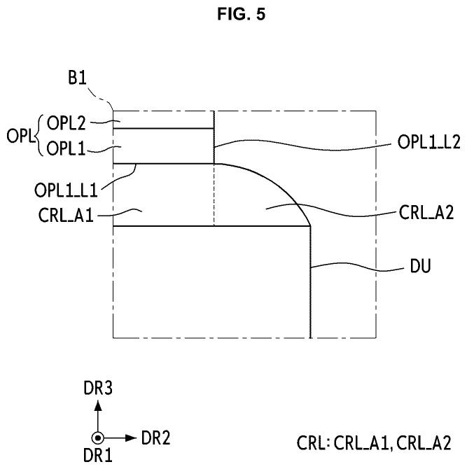

Referring to FIG. 5, compared to FIG. 3, the outermost edge of the second portion CRL_A2 of the buffer layer may coincide with the outermost side surface of the overcoat layer OC.

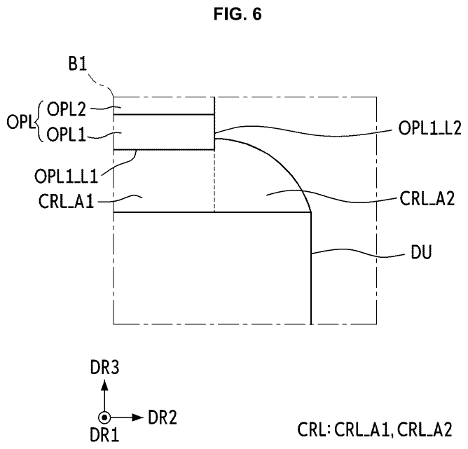

Referring to FIG. 6, compared to FIG. 4, the outermost edge of the second portion CRL_A2 of the buffer layer may coincide with the outermost side surface of the overcoat layer OC.

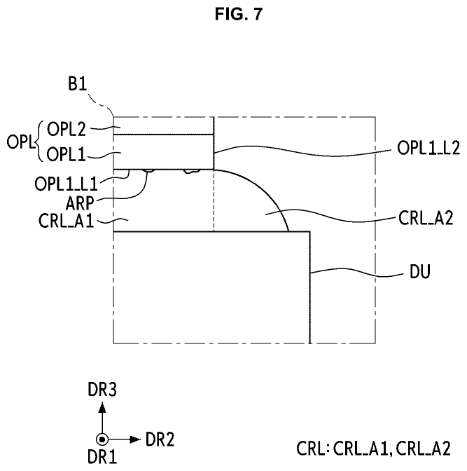

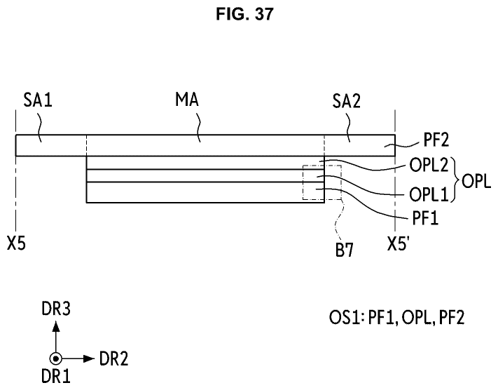

First, referring to FIGS. 2 and 7, an adhesive residue pattern ARP may be positioned on the first surface OPL1_L1 of the optical substrate. The adhesive residue pattern ARP may be a residue remaining on the first surface OPL1_L1 of the optical substrate after a first protective film PF1 including an adhesive layer positioned directly below the optical substrate OPL1 is removed during the process of manufacturing the display device of FIGS. 37 to 39 and FIG. 41 described below, as a low-adhesion material.

Next, referring to FIGS. 7 to 10, compared to FIGS. 3 to 6, respectively, the adhesive residue pattern ARP may be positioned on the first surface OPL1_L1 of the optical substrate, and the buffer layer CRL may be in direct contact with the first surface OPL1_L1 of the optical substrate and the adhesive residue pattern ARP.

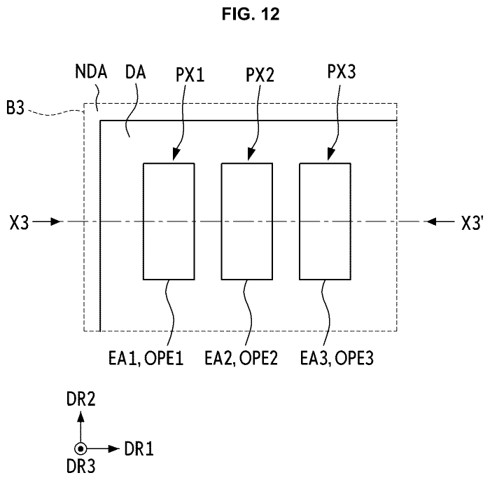

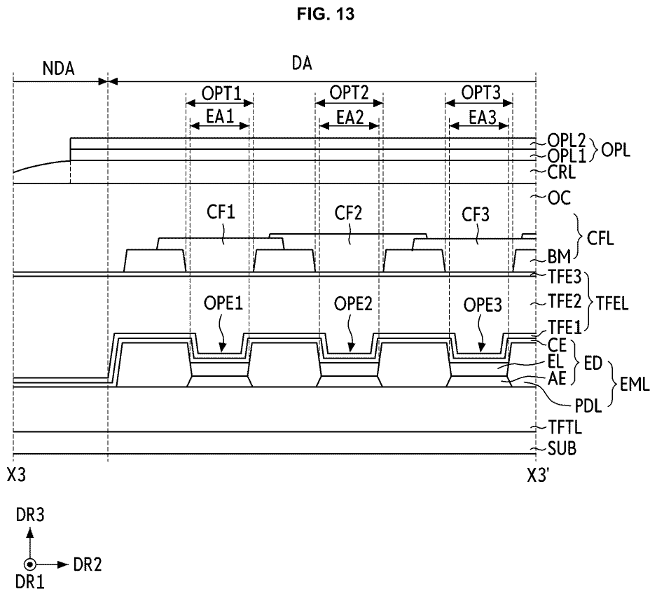

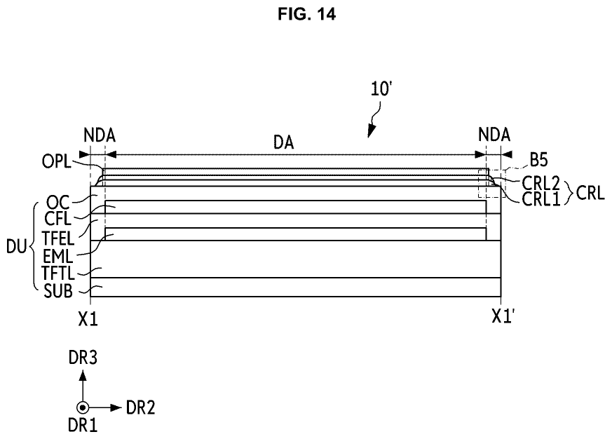

FIG. 11 is a plan view illustrating a display device of a display structure DU according to some embodiments, FIG. 12 is an enlarged plan view of portion B3 of FIG. 11, and FIG. 13 is a cross-sectional view taken along the line X3-X3′ of FIG. 12.

First, referring to FIG. 11, the display layer of the display structure DU may include a display area DA and a non-display area NDA. A plurality of pixels PX may be located in the display area DA. Each of the plurality of pixels PX may be defined as a minimum unit emitting light. The non-display area NDA may surround the display area DA.

Next, referring to FIG. 12, the display layer may include a first pixel PX1, a second pixel PX2, and a third pixel PX3 located in the display area DA. In some embodiments, the second pixel PX2 and the third pixel PX3 may be arranged in the first direction DR1 with respect to the first pixel PX1, but are not limited thereto.

The first pixel PX1 may include a first light emitting area EA1, the second pixel PX2 may include a second light emitting area EA2, and the third pixel PX3 may include a third light emitting area EA3. The first light emitting area EA1 emits first light of a red color, the second light emitting area EA2 emits second light of a blue color, and the third light emitting area EA3 emits third light of a green color. The color of light emitted from the first to third light emitting areas EA1, EA2, and EA3 may vary depending on the type of light emitting element located in the light emitting element layer EML of FIG. 13 described below.

The first to third light emitting areas EA1, EA2, and EA3 may be defined by a plurality of openings OPE1, OPE2, and OPE3 formed in a pixel defining film of the light emitting element layer EML of FIG. 13 described below, respectively. In some embodiments, the first light emitting area EA1 may be defined by a first opening OPE1 of the pixel defining film, the second light emitting area EA2 may be defined by a second opening OPE2 of the pixel defining film, and the third light emitting area EA3 may be defined by a third opening OPE3 of the pixel defining film.

Next, referring to FIGS. 11, 12 and 13, the light emitting element layer EML may be located on the thin film transistor layer TFTL located on the substrate SUB. The light emitting element layer EML may include a light emitting element ED including an anode AE, a light emitting layer EL, and a cathode CE, and a pixel defining film PDL.

The anode AE of the light emitting element layer EML may be located on the thin film transistor layer TFTL. The anode AE may be electrically connected to a drain electrode of the thin film transistor through connection electrodes.

The pixel defining film PDL of the light emitting element layer EML including the plurality of openings may be located on the thin film transistor layer TFTL and a portion of the anode AE. The pixel defining film PDL may include a first opening OPE1, a second opening OPE2, and a third opening OPE3, and the first opening OPE1, the second opening OPE2, and the third opening OPE3 may expose a portion of the anode AE. The pixel defining film PDL may separate and insulate the anodes AE of the plurality of light emitting elements ED from each other.

The light emitting layer EL of the light emitting element layer may be located on the anode AE. The light emitting layer EL may be an organic light emitting layer made of an organic material.

The cathode CE of the light emitting element layer may be located on the light emitting layer EL. The cathode CE may be implemented in the form of an electrode common to all pixels without being separated for each of the plurality of pixels. The cathode CE may be located on the light emitting layer EL in the first to third light emitting areas EA1, EA2, and EA3, and may be located on the pixel defining film PDL in an area excluding the first to third light emitting areas EA1, EA2, and EA3.

The encapsulation layer TFEL may be located on the cathode CE to cover the plurality of light emitting elements ED. The encapsulation layer TFEL may include at least one inorganic film to prevent or reduce contaminants such as oxygen or moisture permeating into the light emitting element layer EML. The encapsulation layer TFEL may include at least one organic film to protect the light emitting element layer EML from foreign substances such as dust.

The encapsulation layer TFEL may include a first encapsulation layer TFEL1, a second encapsulation layer TFEL2, and a third encapsulation layer TFEL3. The first encapsulation layer TFE1 and the third encapsulation layer TFE3 may be inorganic encapsulation layers, and the second encapsulation layer TFEL2 located between the first encapsulation layer TFE1 and the third encapsulation layer TFE3 may be an organic encapsulation layer.

The color filter layer CFL may be located on the encapsulation layer TFEL. The color filter layer CFL may include a light blocking layer BM, a first color filter CF1, a second color filter CF2, and a third color filter CF3.

The light blocking layer BM may be located on the encapsulation layer TFEL. The light blocking layer BM may include a plurality of holes OPT1, OPT2, and OPT3 that overlap the light emitting areas EA1, EA2, and EA3. A first hole OPT1 may overlap the first light emitting area EA1 or the first opening OPE1, a second hole OPT2 may overlap the second light emitting area EA2 or the second opening OPE2, and a third hole OPT3 may overlap the third light emitting area EA3 or the third opening OPE3. A width of each hole OPT1, OPT2, and OPT3 in the second direction DR2 may be greater than a width of the openings OPE1, OPE2, and OPE3 of the pixel defining film PDL in the second direction DR2. As the width of the holes OPT1, OPT2, and OPT3 of the light blocking layer BM is formed to be greater than the width of the openings OPE1, OPE2, and OPE3 of the pixel defining film PDL, light emitted from the light emitting areas EA1, EA2, and EA3 may be visually recognized by a user not only from a front side of the display device 10 but also from a side surface thereof. The vertical spacing may vary depending on a viewing angle required by the display device 10. The light blocking layer BM may prevent or reduce visible light permeating and mixing colors between the first to third light emitting areas EA1, EA2, and EA3, thereby relatively improving a color reproduction rate of the display device 10. The light blocking layer BM may be a black matrix. The light blocking layer BM may include an inorganic black pigment or an organic black pigment.

The color filters CF1, CF2, and CF3 of the color filter layer CFL may be located on the encapsulation layer TFEL in an area that does not overlap the light blocking layer BM. The color filters CF1, CF2, and CF3 of the color filter layer CFL may be located on the light blocking layer BM in an area that overlaps the light blocking layer BM. The different color filters CF1, CF2, and CF3 may correspond to the different light emitting areas EA1, EA2, and EA3 or openings OPE1, OPE2, and OPE3, and the holes OPT1, OPT2, and OPT3 of the light blocking layer BM, respectively. For example, the first color filter CF1 may correspond to the first light emitting area EA1, the second color filter CF2 may correspond to the second light emitting area EA2, and the third color filter CF3 may correspond to the third light emitting area EA3. The first color filter CF1 may be located in the first hole OPT1 of the light blocking layer BM, the second color filter CF2 may be located in the second hole OPT2 of the light blocking layer BM, and the third color filter CF3 may be located in the third hole OPT3 of the light blocking layer BM. Each of the color filters CF1, CF2, and CF3 may have a larger width in the second direction DR2 in plan view than the holes OPT1, OPT2, and OPT3 of the light blocking layer BM, and some of the color filters CF1, CF2, and CF3 may be directly located on the light blocking layer BM.

The overcoat layer OC may be located on the color filters CF1, CF2, and CF3 and the light blocking layer BM to planarize upper ends of the color filters CF1, CF2, and CF3 and the light blocking layer BM. The overcoat layer OC may be a colorless light-transmitting layer having no color in a visible light band. For example, the overcoat layer OC may include a colorless light-transmitting organic material such as an acryl-based resin.

The buffer layer CRL may be located directly on the overcoat layer OC. The buffer layer CRL may be located directly on the overcoat layer OC to physically protect the layers overlapping the buffer layer CRL from shock transmitted from the outside. As the buffer layer CRL physically protects the layers overlapping the buffer layer CRL from the shock transmitted from the outside, reliability of the layers overlapping the buffer layer CRL may be relatively improved.

The optical substrate OPL1 may be located directly on the buffer layer CRL. The optical substrate OPL1 may be located directly on the buffer layer CRL to planarize a surface opposite to a surface of the buffer layer CRL overlapping the optical substrate OPL1 facing the overcoat layer OC. As the optical substrate OPL1 planarizes the surface opposite to the surface of the buffer layer CRL facing the overcoat layer OC, a surface quality of the buffer layer CRL is relatively improved. As a result, because the light provided from the light emitting element layer EML overlapping the buffer layer CRL is not refracted or interfered with by the curvature of the surface of the buffer layer CRL, the light may be evenly visually recognized by the user without distortion. A surface opposite to a surface of the buffer layer CRL that does not overlap the optical substrate OPL1 that faces the overcoat layer OC may form a curved shape due to a surface tension of the material constituting the buffer layer CRL, because of being not planarized. The portion of the buffer layer CRL that does not overlap the optical substrate OPL1 is positioned in the non-display area, and is unrelated to the light provided from the light emitting element layer EML being visually recognized by the user.

The optical functional layer OPL2 may be located on the optical substrate OPL1. In some embodiments, the optical functional layer OPL2 may be an anti-glare layer. In some embodiments, the optical functional layer OPL2 may diffusely reflect light transmitted from the outside. In some embodiments, the optical functional layer OPL2 has uneven surfaces formed or particles added on the inside, so that external light may be scattered on the uneven surfaces or the particle surfaces. In some embodiments, the optical functional layer OPL2 may further include an anti-reflection layer, an anti-fingerprint layer, etc.

FIG. 14 is a cross-sectional view of a display device 10′ according to some embodiments of FIG. 1 taken along the line X1-X1′.

Referring to FIG. 14, a display device 10′ may include a display structure DU, a buffer layer CRL positioned on the display structure DU, and an optical member OPL positioned on the buffer layer CRL. The display structure DU may include a substrate SUB, a thin film transistor layer TFTL positioned on the substrate SUB, a light emitting element layer EML positioned on the thin film transistor layer TFTL, an encapsulation layer TFEL positioned on the light emitting element layer EML, a color filter layer CFL positioned on the encapsulation layer TFEL, and an overcoat layer OC positioned on the color filter layer CFL.

The buffer layer CRL positioned on the display structure DU may be positioned in the display area or the non-display area. The buffer layer CRL may include a first buffer layer CRL1 and a second buffer layer CRL2.

The first buffer layer CRL1 may be positioned directly on the overcoat layer OC of the display structure DU in the display area DA and the non-display area NDA. The first buffer layer CRL1 may include an organic material. In some embodiments, the first buffer layer CRL1 may include an insulating material, such as a polymeric resin. In some embodiments, the first buffer layer CRL1 may include a photocurable resin. In some embodiments, the first buffer layer CRL1 may include an ultraviolet (UV)-curable urethane acrylate resin. In addition, the first buffer layer CRL1 may serve to bond the display structure DU and the second buffer layer CRL2 and may include an optical adhesive resin (OCR).

The second buffer layer CRL2 may be positioned directly on the first buffer layer CRL1 in the display area DA and the non-display area NDA. The second buffer layer CRL2 may include an organic material. According to some embodiments, the second buffer layer CRL2 may include an insulating material, such as a polymeric resin. According to some embodiments, the second buffer layer CRL2 may include a photocurable resin. According to some embodiments, the second buffer layer CRL2 may include an ultraviolet (UV)-curable urethane acrylate resin.

The buffer layer CRL of the display device 10′ including the first buffer layer CRL1 and the second buffer layer CRL2 may protect the layers of the display structure DU of the display device 10′ from shock transmitted from the outside and further relatively reduce the possibility of the display device 10′ being damaged by the shock transmitted from the outside, thereby further relatively improving reliability of the display device 10′.

The first buffer layer CRL1 may protect the layers of the display structure DU of the display device 10′ from the shock transmitted from the outside. The first buffer layer CRL1 may disperse the shock transmitted from the outside that is not absorbed by the second buffer layer CRL2. According to some embodiments, the first buffer layer CRL1 may have physical properties that disperse the shock transmitted from the outside that is not absorbed by the second buffer layer CRL2. According to some embodiments, the first buffer layer CRL1 may have a specific range of Young's modulus values. According to some embodiments, the first buffer layer CRL1 may have a Young's modulus value of 100 MPa or less.

The second buffer layer CRL2 may protect the layers of the display structure DU of the display device 10′ from the shock transmitted to the display structure DU from the outside.

The second buffer layer CRL2 may have physical properties that mitigate the shock transmitted from the outside. In some embodiments, the second buffer layer CRL2 may have a specific range of Young's modulus values. In some embodiments, the second buffer layer CRL2 may have a Young's modulus value of 700 MPa to 800 MPa.

The first buffer layer CRL1 and the second buffer layer CRL2 may have different physical properties. In some embodiments, the first buffer layer (CRL1) and the second buffer layer (CRL2) may have different Young's modulus. In some embodiments, the Young's modulus of the second buffer layer CRL2 may be greater than the Young's modulus of the first buffer layer CRL1. In some embodiments, the Young's modulus of the second buffer layer CRL2 may be 700 MPa to 800 MPa, and the Young's modulus of the first buffer layer CRL1 may be 100 MPa or less.

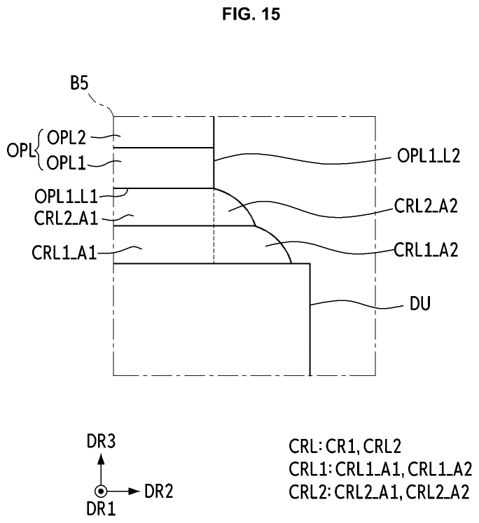

FIG. 15 is an enlarged cross-sectional view of area B5 of FIG. 14.

Referring to FIGS. 14 and 15, the buffer layer CRL may include a first portion CRL_A1 overlapping the optical member OPL and a second portion CRL_A2 that does not overlap the optical member OPL and is positioned outside the first portion CRL_A1. The first buffer layer CRL1 may include a first portion CRL1_A1 of the first buffer layer overlapping the optical member OPL and a second portion CRL1_A2 that does not overlap the optical member OPL and is positioned outside the first portion CRL1_A1 of the first buffer layer. The second buffer layer CRL2 may include a first portion CRL2_A1 of the second buffer layer overlapping the optical member OPL and a second portion CRL2_A2 that does not overlap the optical member OPL and is positioned outside the first portion CRL2_A1 of the second buffer layer. In addition, the first portion CRL_A1 of the buffer layer may include the first portion CLR1_A1 of the first buffer layer and the first portion CLR2_A1 of the second buffer layer. The second portion CRL_A2 of the buffer layer may include the second portion CLR1_A2 of the first buffer layer and the second portion CLR2_A2 of the second buffer layer.

The first portion CRL1_A1 of the first buffer layer may be positioned in the display area DA and may be further positioned in the non-display area NDA. Only the first portion CRL1_A1 of the first buffer layer may overlap the optical member OPL in the display area DA and the non-display area NDA.

A surface opposite to a surface of the first portion CRL1_A1 of the first buffer layer facing the overcoat layer OC may be in direct contact with a surface opposite to a surface of the first portion CRL2_A1 of the second buffer layer facing the optical substrate OPL1. The surface opposite to the surface of the first portion CRL1_A1 of the first buffer layer facing the overcoat layer OC may not be substantially flat.

A surface opposite to a surface of the first portion CRL2_A1 of the second buffer layer facing the first buffer layer CRL1 may be in direct contact with a first surface OPL1_L1 of the optical substrate included in the optical member OPL. The surface opposite to the surface of the first portion CRL2_A1 of the second buffer layer facing the first buffer layer CRL1 may be planarized to correspond to a shape of the first surface OPL1_L1 of the optical substrate. As the surface opposite to the surface of the first portion CRL2_A1 of the second buffer layer facing the first buffer layer CRL1 is planarized by the first surface OPL1_L1 of the optical substrate, a surface quality of the display device 10 may be relatively improved, and a display quality of the display device 10 may be relatively improved.

The second portion CRL1_A2 of the first buffer layer may only be positioned in the non-display area NDA. The surface opposite to the surface of the second portion CRL1_A2 of the first buffer layer facing the overcoat layer OC may include a curved surface. The outermost edge of the second portion CRL1_A2 of the first buffer layer may be positioned inward relative to the outermost side surface of the overcoat layer OC.

The second portion CRL2_A2 of the second buffer layer may only be positioned in the non-display area NDA. The surface opposite to the surface of the second portion CRL2_A2 of the second buffer layer facing the first buffer layer CRL1 may include a curved surface. The outermost edge of the second portion CRL2_A2 of the second buffer layer may be positioned inward relative to the outermost edge of the second portion CRL1_A2 of the first buffer layer.

The first portion CRL2_A1 of the second buffer layer and the second portion CRL2_A2 of the second buffer layer may have different physical properties. In some embodiments, the first portion CRL2_A1 of the second buffer layer and the second portion CRL2_A2 of the second buffer layer may have different surface curing rates. In some embodiments, the first portion CRL2_A1 of the second buffer layer may have a higher surface curing rate than the second portion CRL2_A2 of the second buffer layer.

The curved surfaces included in the second portion CRL_A2 of the buffer layer may include two curved surfaces of the same or different shapes that are continuously connected to each other. In some embodiments, the curved surface included in the second portion CRL_A2 of the buffer layer may include a single curved surface that is continuously connected. In some embodiments, the curved surface included in the second portion CRL_A2 of the buffer layer may include two curved surfaces of the same or different shapes that are discontinuous with each other.

When a displacement from a surface of the buffer layer CRL facing the overcoat layer OC to the top of a surface opposite to the surface of the buffer layer CRL facing the overcoat layer OC is referred to as a height of the buffer layer CRL, a height of the first portion CRL_A1 of the buffer layer and a height of the second portion CRL_A2 of the buffer layer may be different from each other. In some embodiments, the height of the second portion CRL_A2 of the buffer layer may be greater than the height of the first portion CRL_A1 of the buffer layer. In some embodiments, the height of the first portion CRL_A1 of the buffer layer may be equal to the height of the second portion CRL_A2 of the buffer layer.

Referring to FIG. 15, the height of the first portion CRL_A1 of the buffer layer may coincide with the height of the second portion CRL_A2 of the buffer layer, the outermost edge of the second portion CRL1_A2 of the first buffer layer may be positioned inward relative to the outermost side surface of the overcoat layer OC, and the curved surface included in the second portion CRL_A2 of the buffer layer may include two curved surfaces of the same or different shapes that are continuously connected to each other.

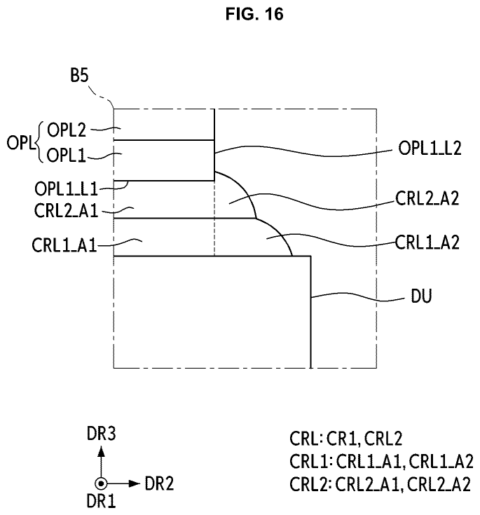

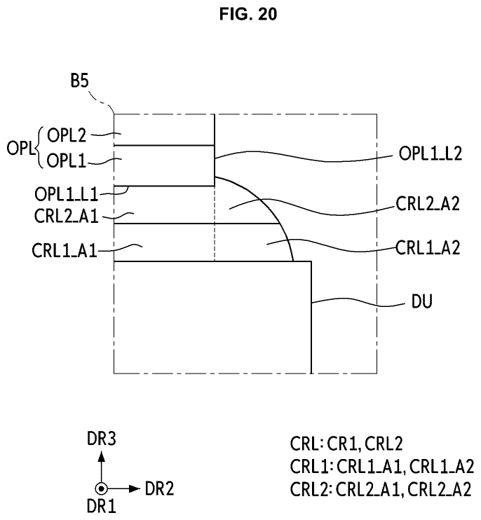

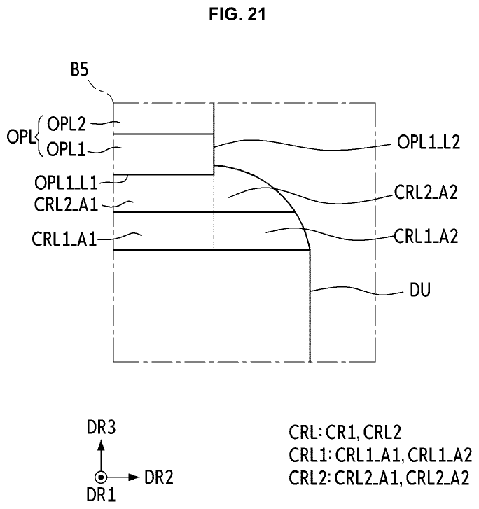

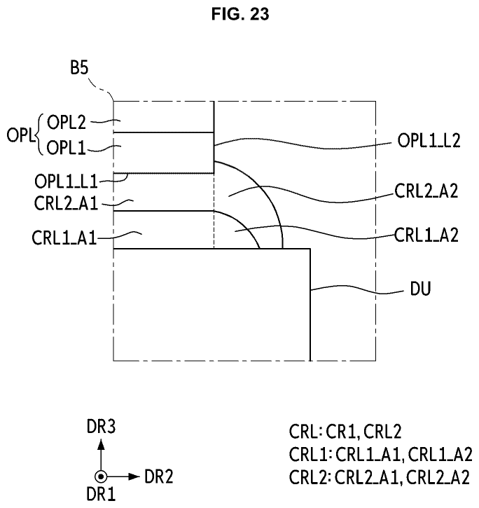

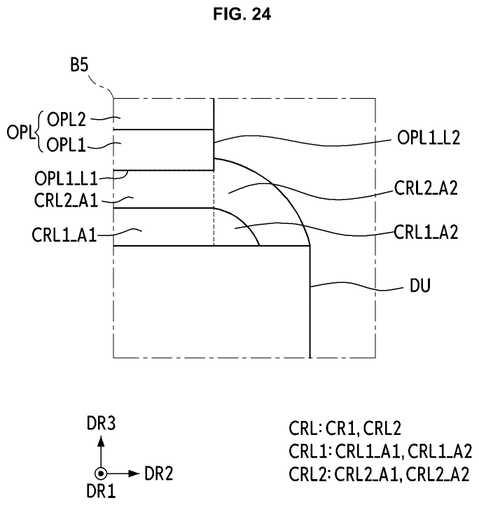

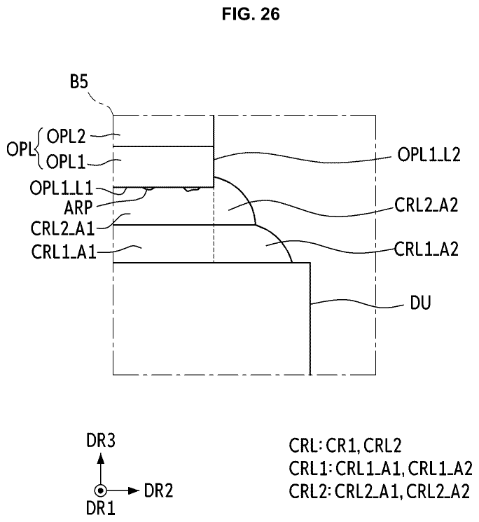

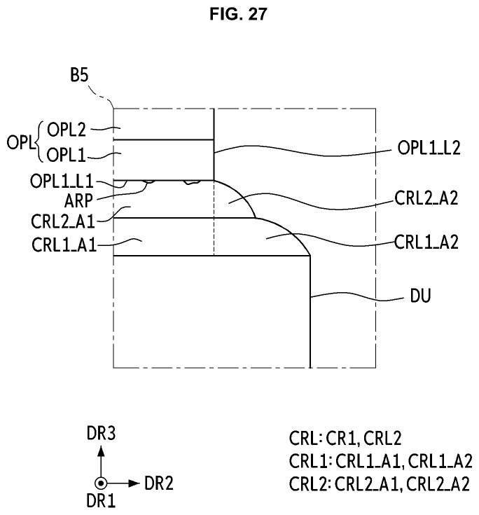

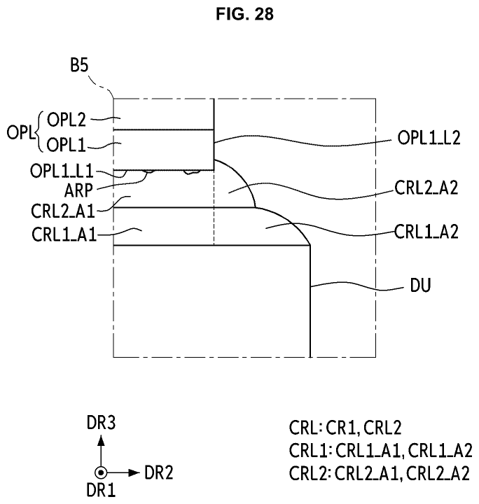

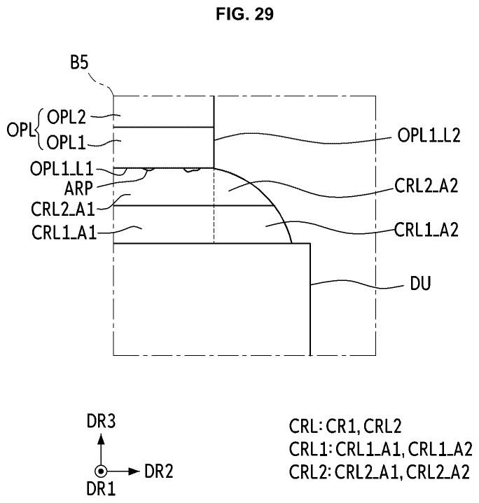

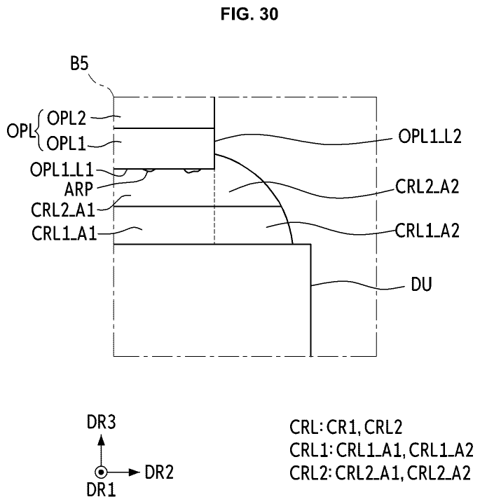

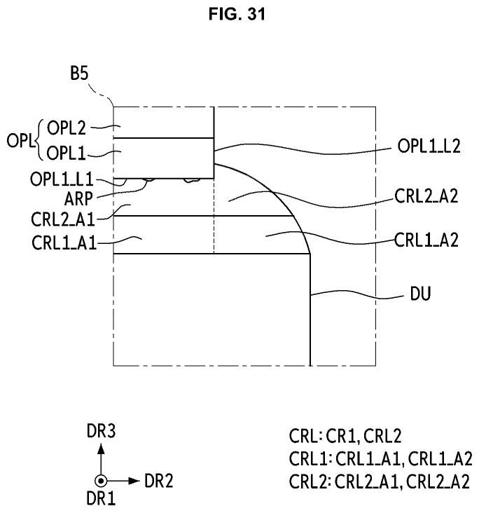

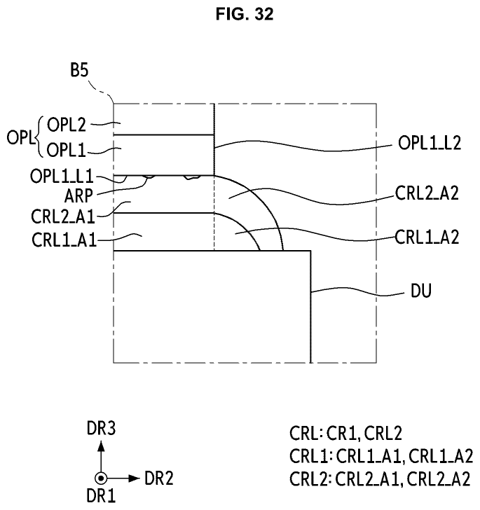

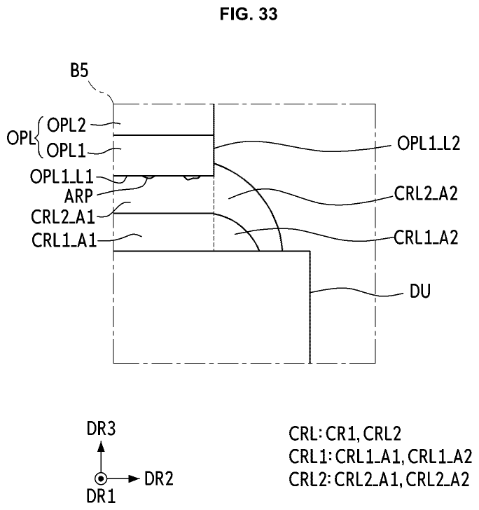

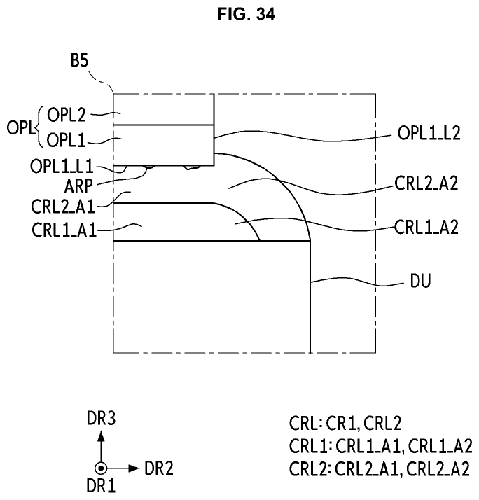

FIGS. 16 to 34 are cross-sectional views illustrating modified examples of the display device, which are enlarged views of portion B5 of FIG. 14. Hereinafter, the differences will be mainly described and duplicated descriptions will be omitted.

Referring to FIG. 16, compared to FIG. 15, the height of the second portion CRL_A2 of the buffer layer may be greater than the height of the first portion CRL_A1 of the buffer layer, and the second portion CRL_A2 of the buffer layer may be in contact with the second surface OPL_L2 of the optical substrate.

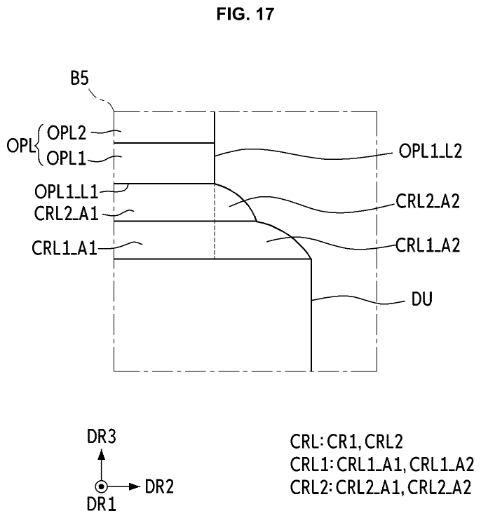

Referring to FIG. 17, compared to FIG. 15, the outermost edge of the second portion CRL_A2 of the buffer layer may coincide with the outermost side surface of the overcoat layer OC.

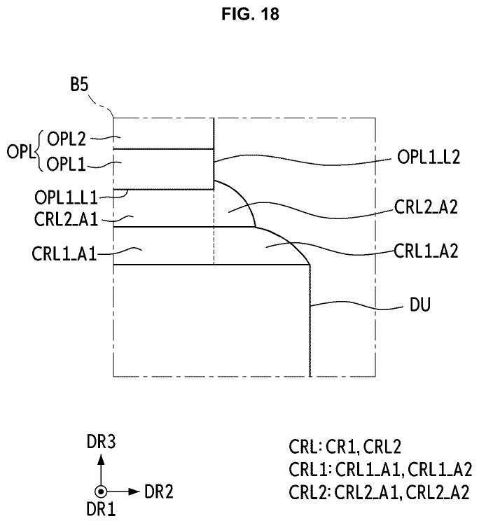

Referring to FIG. 18, compared to FIG. 16, the outermost edge of the second portion CRL_A2 of the buffer layer may coincide with the outermost side surface of the overcoat layer OC.

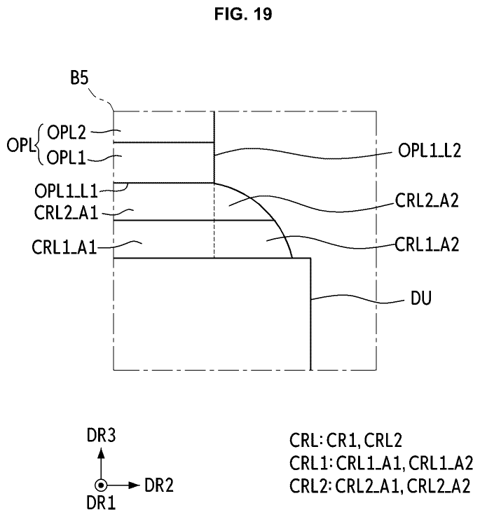

Referring to FIGS. 19 to 21, compared to FIGS. 15, 16, and 18, respectively, the curved surface included in the second portion CRL_A2 of the buffer layer may include a single curved surface that is continuously connected.

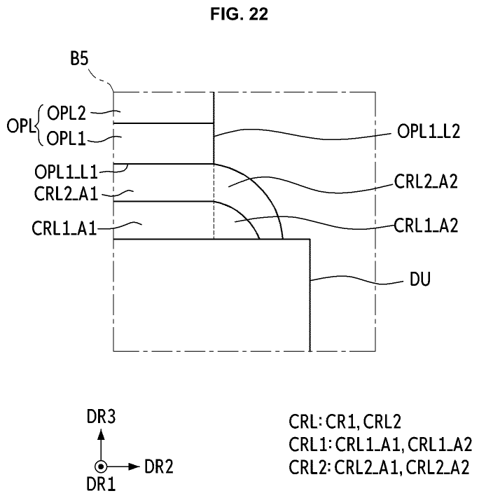

Referring to FIGS. 22 to 24, compared to FIGS. 15, 16, and 18, respectively, the curved surface included in the second portion CRL_A2 of the buffer layer may include two curved surfaces of the same or different shapes that are discontinuous with each other.

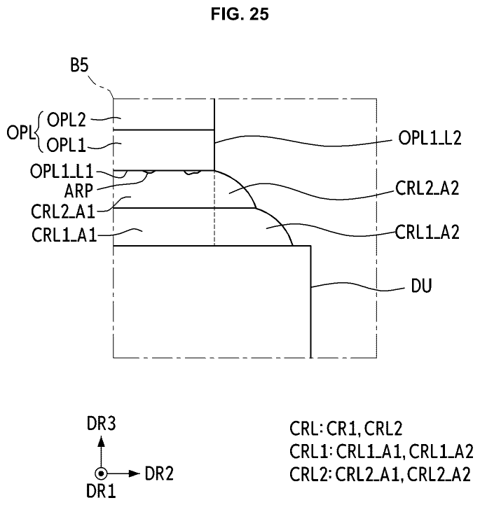

First, referring to FIGS. 14 and 25, an adhesive residue pattern ARP may be positioned on the first surface OPL1_L1 of the optical substrate. The adhesive residue pattern ARP may be a residue remaining on the first surface OPL1_L1 of the optical substrate after a first protective film PF1 including an adhesive layer positioned directly below the optical substrate OPL1 is removed during the process of manufacturing the display device of FIGS. 37 to 39 and FIG. 41 described below, as a low-adhesion material.

Next, referring to FIGS. 25 to 34, compared to FIGS. 15 to 24, respectively, the adhesive residue pattern ARP may be positioned on the first surface OPL1_L1 of the optical substrate, and the first portion CRL2_A1 of the second buffer layer may be in direct contact with the first surface OPL1_L1 of the optical substrate and the adhesive residue pattern ARP.

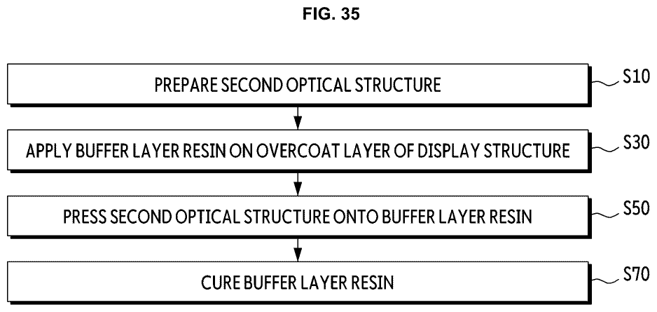

FIG. 35 is a flowchart illustrating aspects of a method of manufacturing a display device according to some embodiments. Although FIG. 35 illustrates various operations in a method of manufacturing a display device, embodiments according to the present disclosure are not limited thereto, and according to various embodiments, the method may include additional operations, or fewer operations, or the order of operations may vary, unless otherwise stated or implied, without departing from the spirit and scope of embodiments according to the present disclosure.

Referring to FIG. 35, a method of manufacturing a display device according to some embodiments may sequentially include an operation (S10) of preparing a second optical structure, an operation (S30) of applying a buffer layer resin on an overcoat layer of a display structure, an operation (S50) of pressing the second optical structure onto the buffer layer resin, and an operation (S70) of curing the buffer layer resin.

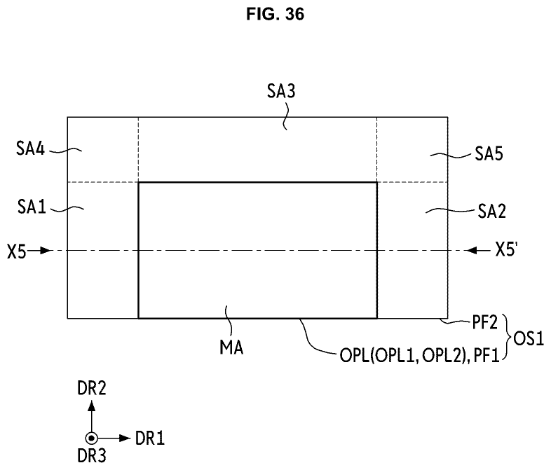

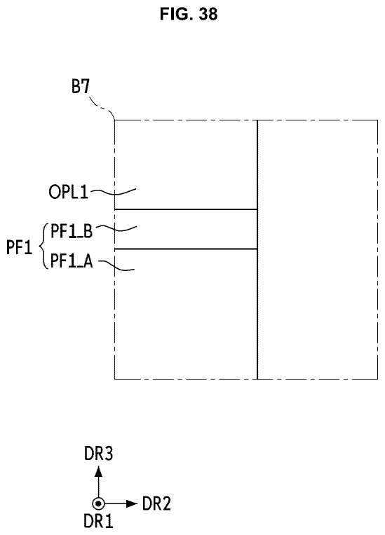

FIGS. 36 to 38 are views for describing a first optical structure OS1. FIG. 36 is a plan view of a first optical structure OS1. FIG. 37 is a cross-sectional view of the first optical structure OS1 of FIG. 36 taken along the line X5-X5′. FIG. 38 is an enlarged cross-sectional view of portion B7 of FIG. 37.

First, referring to FIGS. 36 and 37, the first optical structure OS1 may include a first protective film PF1, an optical member OPL including an optical substrate OPL1 positioned on the first protective film PF1 and an optical functional layer OPL2 positioned on the optical substrate OPL1, and a second protective film PF2 positioned on the optical member OPL.

The second protective film PF2 of the first optical structure OS1 may include a main area MA overlapping the optical member OPL, and first to fifth border areas SA1, SA2, SA3, SA4, and SA5 that do not overlap the optical member OPL and extend further along the first direction DR1 and the second direction DR2 than the optical member OPL.

Next, referring to FIGS. 37 and 38, the first protective film PF1 may include a first protective film functional layer PF1_A and a first protective film adhesive layer PF1_B positioned on the first protective film functional layer PF1_A. The first protective film functional layer PF1_A may serve to protect the optical member OPL. The first protective film adhesive layer PF1_B may serve as an adhesive layer that adheres the optical substrate OPL1 of the optical member OPL located on the first protective film PF1 and the first protective film functional layer PF1_A.

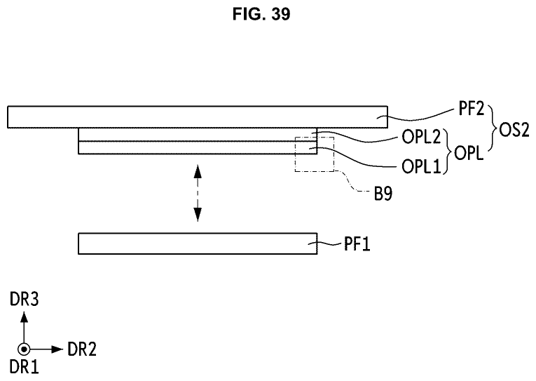

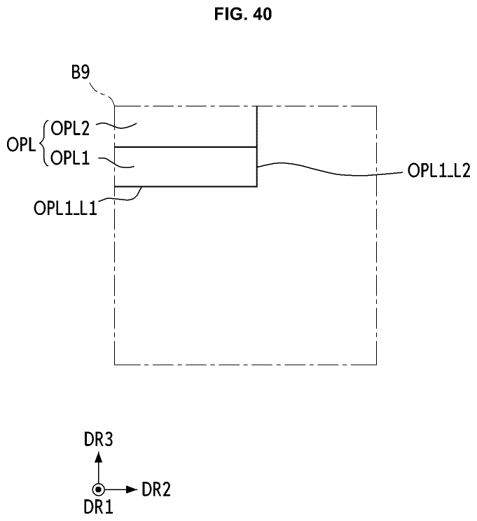

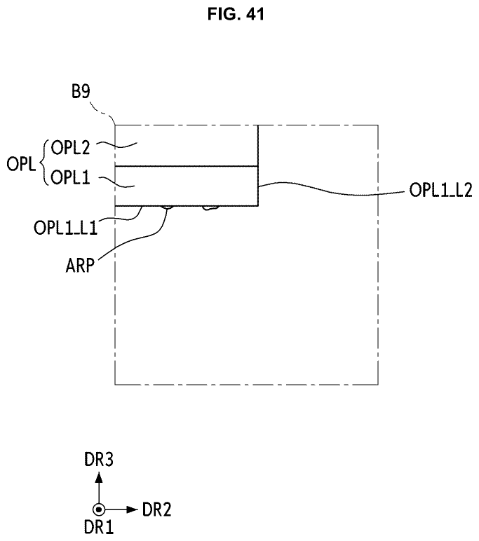

FIGS. 39 to 41 are views for describing the operation (S10) of preparing the second optical structure OS2. FIG. 40 is a cross-sectional view illustrating the second optical structure OS2 enlarged from portion B9 of FIG. 39. FIG. 41 is a cross-sectional view illustrating a modified example of the second optical structure OS2, which is an enlarged view of portion B9 of FIG. 39.

Referring to FIG. 39, the second optical structure OS2 may be formed by peeling off the first protective film PF1 of the first optical structure OS1.

Referring to FIGS. 38, 39, and 40, the first protective film PF1 adhered to the first surface OPL1_L1 of the optical substrate of the first optical structure OS1 by the first protective film adhesive layer PF1_B of the first protective film PF1 may be peeled off in the operation (S10) of preparing the second optical structure OS2, and an adhesive residue may not exist on the first surface OPL1_L1 of the optical substrate.

The first protective film PF1 adhered to the first surface OPL1_L1 of the optical substrate of the first optical structure OS1 by the first protective film adhesive layer PF1_B of the first protective film PF1 may be peeled off in the operation (S10) of preparing the second optical structure OS2, and a portion of the first protective film adhesive layer PF1_B remains on the first surface OPL1_L1 of the optical substrate, so that an adhesive residue pattern ARP may exist on the first surface OPL1_L1 of the optical substrate.

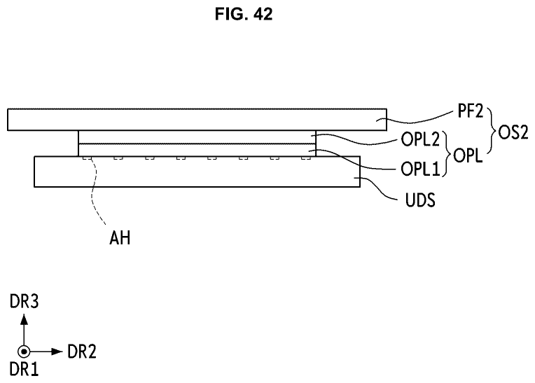

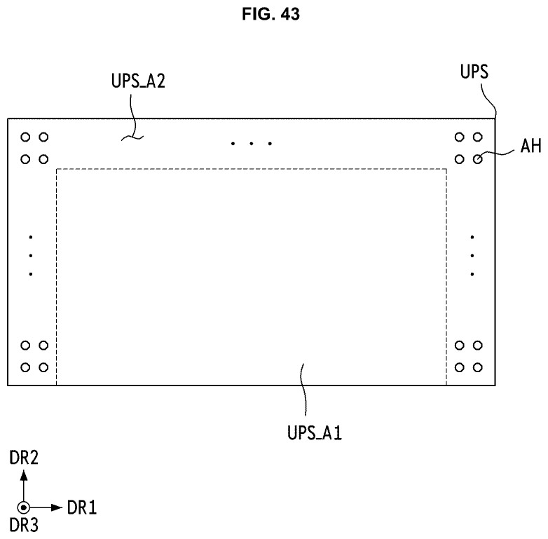

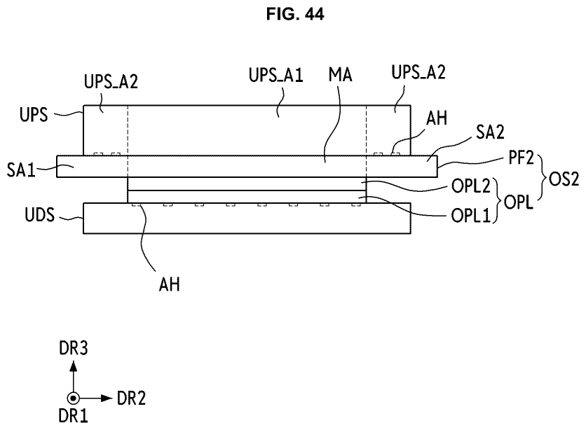

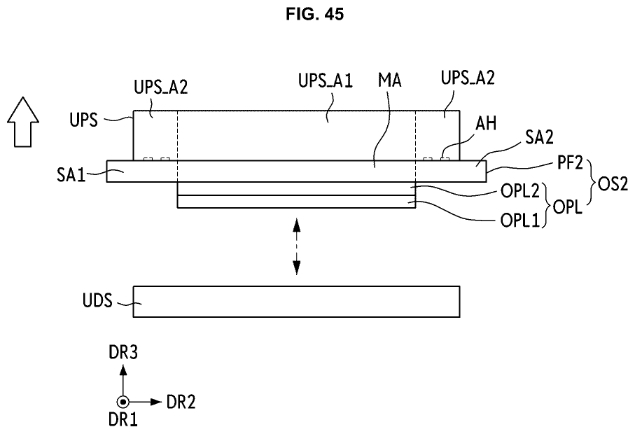

FIGS. 42 to 45 are views for describing a process of preparing the operation of pressing the second optical structure OS2 onto the buffer layer resin CR. FIG. 42 is a view for describing an operation of adsorbing a surface opposite to a surface of the optical substrate OPL1 of the second optical structure OS2 facing the optical functional layer OPL2 to a lower stage UDS. FIG. 43 is a view for describing an upper stage UPS. FIG. 44 is a view for describing an operation of adsorbing a surface opposite to a surface of the second protective film PF2 of the second optical structure OS2 facing the optical functional layer OPL2 to the upper stage UPS. FIG. 45 is a view for describing an operation of detaching the lower stage UDS adsorbed to the optical substrate OPL1 of the second structure OS2.

First, referring to FIG. 42, the surface opposite to surface of the optical substrate OPL1 of the second optical structure OS2 facing the optical functional layer OPL2 may be fixed by vacuum adsorption on a lower stage UDS including a plurality of adsorption holes AH. Through the operation of adsorbing the second optical structure OS2 to the lower stage UDS, the surface opposite to the surface of the optical substrate OPL1 facing the optical functional layer OPL2 may secure flatness.

Next, FIG. 43 is a view for describing an upper stage UPS.

Referring to FIGS. 36 and 43, the upper stage UPS may include a first area UPS_A1 and a second area UPS_A2. The first area UPS_A1 of the upper stage may overlap the main area MA of the second protective film PF2 of the second optical structure OS2. The second area UPS_A2 of the upper stage may overlap the first to fifth border areas SA1, SA2, SA3, SA4, and SA5 of the second protective film PF2 of the second optical structure OS2. The first area UPS_A1 of the upper stage may include a light-transmitting material. In some embodiments, the first area UPS_A1 of the upper stage may include quartz. The first area UPS_A1 of the upper stage may include a light-blocking material.

Next, referring to FIGS. 42 and 44, the first area UPS_A1 of the upper stage does not adsorb the main area MA of the second protective film PF2, and only the second area UPS_A2 of the upper stage may adsorb the border areas SA1, SA2, SA3, SA4, and SA5 of the second protective film PF2. The second area UPS_A2 of the upper stage may include a plurality of adsorption holes AH for adsorbing the border areas SA1, SA2, SA3, SA4, and SA5 of the second protective film PF2 of the second structure OS2. The adsorption method may be a vacuum adsorption method.

In some embodiments, the first area UPS_A1 adsorbs only the main area MA of the second protective film PF2, and only the second area UPS_A2 of the upper stage may not adsorb the border areas SA1, SA2, SA3, SA4, and SA5 of the second protective film PF2. The first area UPS_A1 of the upper stage is electrostatically adsorbed to adsorb the main area MA of the second protective film PF2, so that the main area MA of the second protective film PF2 may be adsorbed to the first area UPS_A1 of the upper stage.

FIG. 45 is a view for describing an operation of detaching the lower stage UDS adsorbed to an optical substrate OPL1 of a second structure OS2.

Referring to FIG. 45, the second structure OS2 is fixed in a state of being absorbed to the upper stage UPS, so that only the lower stage UDS may be detached. In addition, a surface opposite to a surface of the optical substrate OPL1 of the second structure OS2 with the lower stage UDS detached facing the optical functional layer OPL2 may be maintained in a state where flatness is secured.

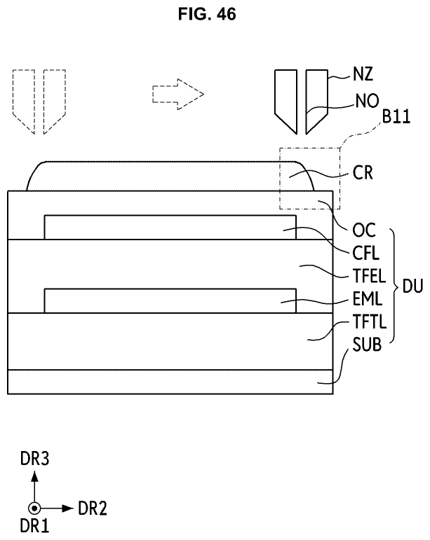

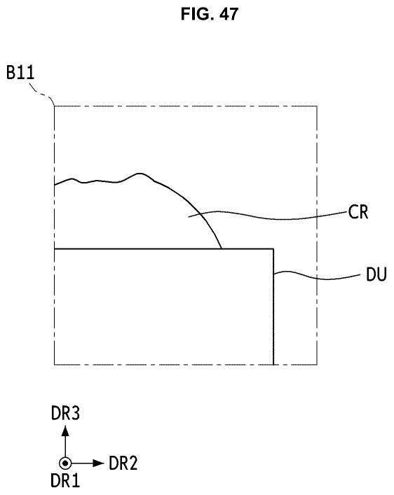

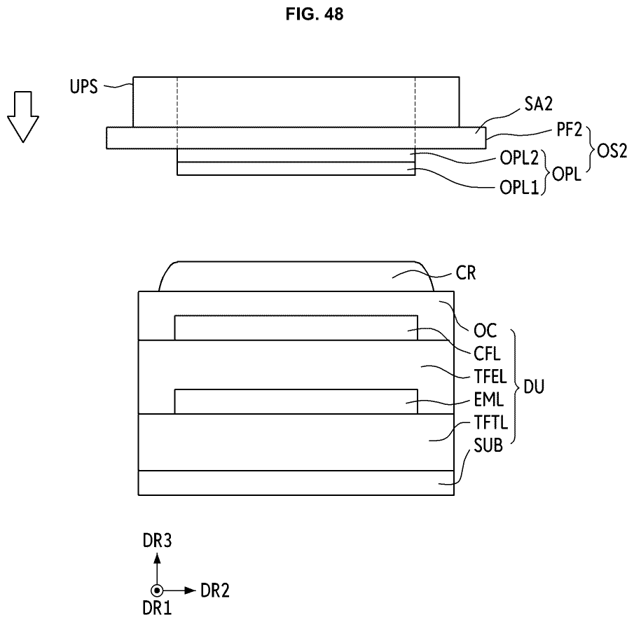

FIGS. 46 and 47 are views for describing the operation (S30) of applying the buffer layer resin CR on the overcoat layer OC of the display structure DU. FIG. 46 is a view for describing a process of applying the buffer layer resin CR on the overcoat layer OC of the display structure DU. FIG. 47 is an enlarged cross-sectional view of area B11 illustrated in FIG. 46.

Referring to FIGS. 46 and 47, the buffer layer resin CR may be directly applied through a discharge portion NO of a nozzle NZ directly on the overcoat layer OC of the display structure DU including the substrate SUB, the thin film transistor layer TFTL, the light emitting element layer EML, the encapsulation layer TFEL, the color filter layer CFL, and the overcoat layer OC, and may be applied so that the outermost edge of the buffer layer resin CR is positioned inward relative to a side surface of the display structure DU. The process of applying the buffer layer resin CR on the overcoat layer OC of the display structure DU may be performed by slit coating.

A surface opposite to a surface of the buffer layer resin CR facing the display structure DU may not be substantially flat due to the characteristics of the material constituting the buffer layer resin CR or the slit coating.

As described above, FIGS. 42 to 45 illustrate the process of preparing the operation (S50) of pressing the second optical structure OS2 onto the buffer layer resin CR, which may be performed before and after the operation (S30) of applying the buffer layer resin CR on the overcoat layer OC of the display structure DU or in parallel with the operation (S30) of applying the buffer layer resin CR on the overcoat layer OC of the display structure DU.

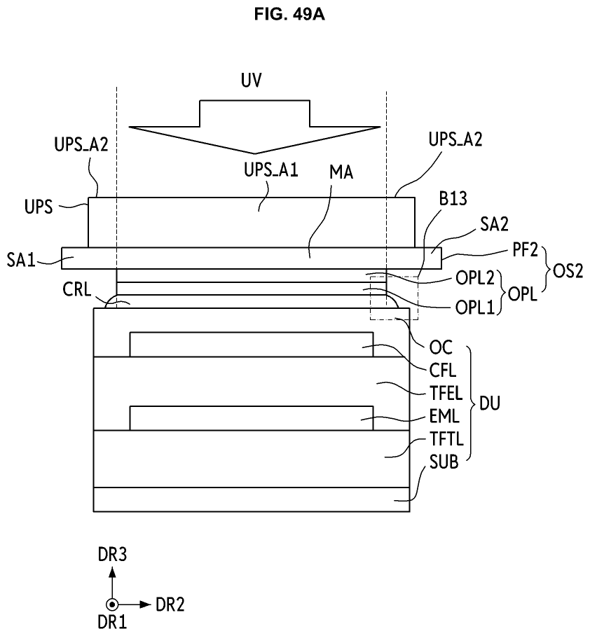

FIG. 48 is a view for describing the operation (S50) of pressing the second optical structure OS2 onto the buffer layer resin CR.

Referring to FIG. 48, the second optical structure OS2 may be positioned on the buffer layer resin CR while being adsorbed on the upper stage UPS, thereby pressing the buffer layer resin CR so that the optical substrate OPL1 of the second optical structure OS2 faces the buffer layer resin CR applied on the display structure DU.

Referring to FIGS. 3 to 6, 46, 47, and 48, in the operation (S50) of pressing the second optical structure OS2 onto the buffer layer resin CR, planarization may be performed so that a surface opposite to a surface of the buffer layer resin CR in contact with the first surface OPL1_L1 of the optical substrate facing the overcoat layer OC corresponds to the flat first surface OPL1_L1 of the optical substrate. In addition, the buffer layer resin CR may be pressed in the form of the buffer layer CRL as illustrated in FIGS. 3 to 6.

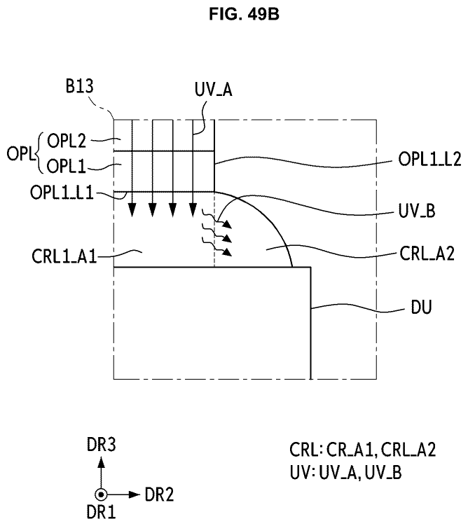

FIG. 49 is a view for describing the operation (S70) of curing the buffer layer resin CR.

Referring to FIGS. 48 and 49, a buffer layer CRL positioned on the display structure DU may be formed through a process of curing the buffer layer resin CR. The operation (S70) of curing the buffer layer resin may be an ultraviolet curing operation. Ultraviolet (UV) light may be irradiated from the upper stage UPS that adsorbs the second optical structure OS2. As described above, because the second area UPS_A2 of the upper stage UPS includes the light-blocking material and the first area UPS_A1 of the upper stage UPS includes the light-transmitting material, the irradiated ultraviolet (UV) light may be transmitted through only the first area UPS_A1 of the upper stage. Therefore, the ultraviolet (UV) light irradiated from the upper stage UPS may be transmitted through the optical member OPL and the main area MA of the first protective film PF1 overlapping the first area UPS_A1 of the upper stage to be provided to the buffer layer resin CR.

The ultraviolet (UV) light provided to the buffer layer may be directly irradiated (UV_A) in an area overlapping the optical member, and indirectly irradiated (UV_B) by diffraction or the like in an area that does not overlap the optical member. In some embodiments, the UV intensity in the area directly irradiated (UV_A) with UV light and the area indirectly irradiated (UV_B) with UV light may be different. In some embodiments, the UV intensity in the area directly irradiated (UV_A) with UV light may be greater than that of the area indirectly irradiated (UV_B) with UV light. In some embodiments, the UV intensity in the area directly irradiated (UV_A) with UV light may be 1200 mJ or more, and the UV intensity in the area indirectly irradiated (UV_B) with UV light may be less than 1200 mJ.

Referring to FIGS. 3 to 49, in the operation (S70) of curing the buffer layer resin CR, the buffer layer resin CR may be cured into the first portion CRL_A1 of the buffer layer by being directly irradiated (UV_A) with ultraviolet light in the area overlapping the optical member OPL, and may be cured into the second portion CRL_A2 of the buffer layer by being indirectly irradiated (UV_B) with ultraviolet light in the area that does not overlap the optical member OPL.

The degree of crosslinking reaction on the surface of the resin may vary depending on the intensity of ultraviolet light provided during the ultraviolet curing process of the ultraviolet curable resin, the concentration of oxygen exposed to the surface, etc. For example, when irradiated with ultraviolet light of strong intensity, it may promote a crosslinking reaction between the materials that make up the resin, thereby increasing the surface curing rate of the resin. In addition, in an environment with a low oxygen concentration, the reaction with oxygen on the surface is inhibited, which may promote the crosslinking reaction between the materials that make up the buffer layer resin, thereby increasing the surface curing rate of the resin. The surface curing rate refers to the degree to which the surface of the resin has been cross-linked, and may be expressed as Yong's modulus.

The first portion of the buffer layer CRL_A1 may be blocked from oxygen during the ultraviolet curing process due to the optical member OPL positioned directly on the buffer layer resin CR. However, the second portion CRL_A2 of the buffer layer may be exposed to oxygen because there is no configuration positioned on the second portion CRL_A2 of the buffer layer. Therefore, as described above, the first portion CRL_A1 of the buffer layer and the second portion CRL_A2 of the buffer layer may have different physical properties. That is, the surface curing rate of the first portion CRL_A1 of the buffer layer and the surface curing rate of the second portion CRL_A2 of the buffer layer may be different from each other, and the surface curing rate of the first portion CRL_A1 of the buffer layer may be greater than the surface curing rate of the second portion CRL_A2 of the buffer layer. In addition, the Young's modulus of the first portion (CRL_A1) of the buffer layer and the Young's modulus of the second portion (CRL_A2) of the buffer layer may be different from each other, and the Young's modulus of the first portion (CRL_A1) of the buffer layer may be greater than the Young's modulus of the second portion (CRL_A2) of the buffer layer.

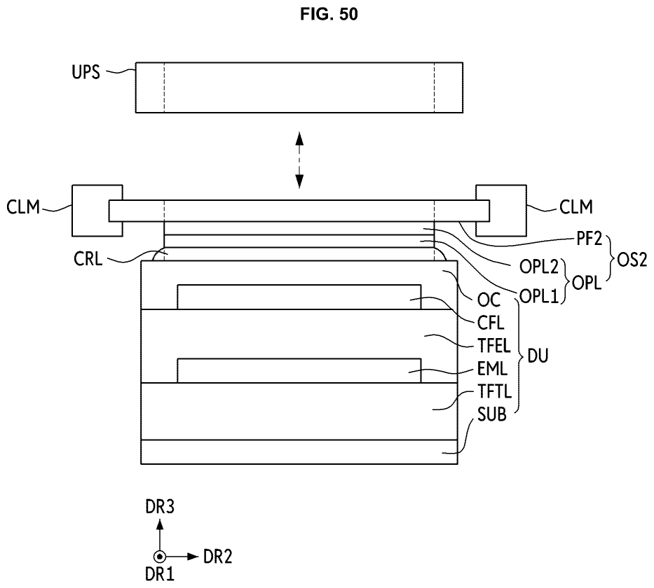

FIG. 50 is a view for describing an operation of detaching the upper stage UPS.

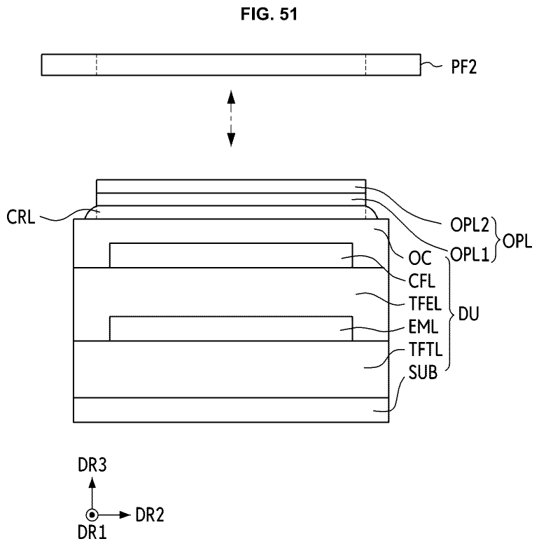

FIG. 51 is a view for describing an operation of peeling off the second protective film PF2 of the second structure OS2.

Referring to FIG. 51, the display device 10 having the structure illustrated in FIG. 2 is manufactured through an operation of peeling off the second protective film PF2 of the second structure OS2.

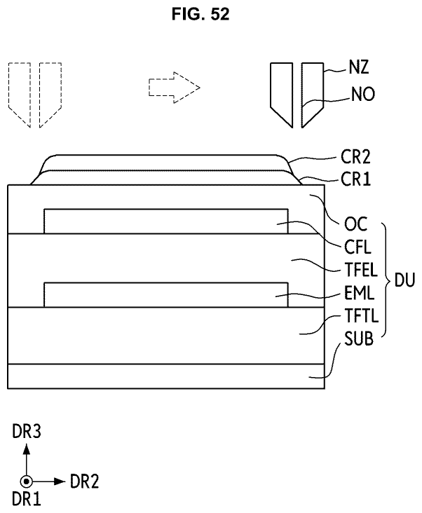

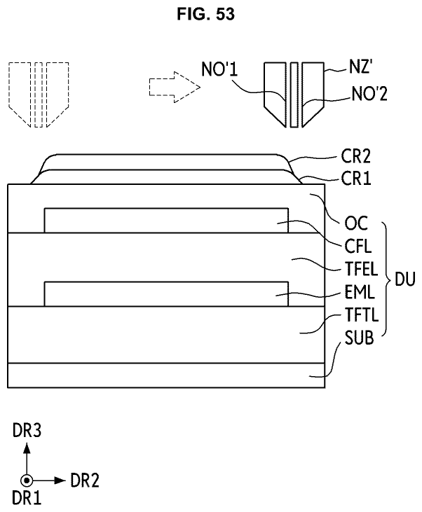

FIGS. 52 and 53 are views for describing operations of applying a first buffer layer resin CR1 and a second buffer layer resin CR2 in the method of manufacturing the display device 10′ illustrated in FIG. 14. The first buffer layer resin CR1 may be directly applied directly on the overcoat layer OC of the display structure DU including the substrate SUB, the thin film transistor layer TFTL, the light emitting element layer EML, the encapsulation layer TFEL, the color filter layer CFL, and the overcoat layer OC, and may be applied so that the outermost edge of the first buffer layer resin CR1 is positioned inward relative to a side surface of the display structure DU. The second buffer layer resin CR2 may be applied directly on the first buffer layer resin CR1, and may be applied so that the outermost edge of the second buffer layer resin CR2 is positioned inward relative to the outermost edge of the first buffer layer resin CR1.

The process of applying the buffer layer resin CR on the overcoat layer OC of the display structure DU may be performed by slit coating.

Referring to FIG. 52, the first buffer layer resin CR1 and the second buffer layer resin CR2 may be applied and stacked by sequentially performing two application processes, respectively.

Referring to FIG. 53, the first buffer layer resin CR1 and the second buffer layer resin CR2 may be applied and stacked in a single dual-coating manner in which the first buffer layer resin CR1 and the second buffer layer resin CR2 are sequentially applied from each of the discharge portions NO′1 and NO′2 of one nozzle NZ′

The display device according to some embodiments may be applied to various electronic devices. An electronic device according to some embodiments may include the display device described above, and may further include a module or device having additional functions in addition to the display device.

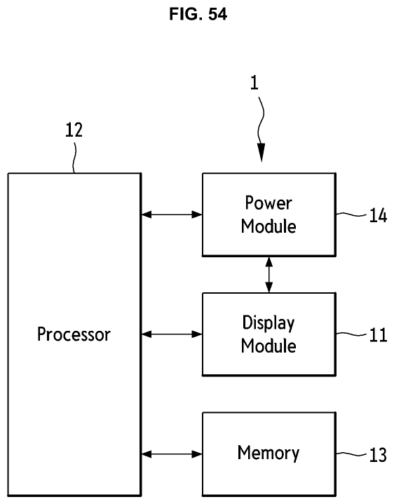

FIG. 54 is a block diagram of an electronic device according to some embodiments. Referring to FIG. 54, an electronic device 1 according to some embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

Data information necessary for an operation of the processor 12 or the display module 11 may be stored in the memory 13. When the processor 12 executes an application stored in the memory 13, image data signals and/or input control signals may be transmitted to the display module 11, and the display module 11 may process the provided signals and output image information through a display screen.

The power module 14 may include a power supply module, such as a power adapter or a battery device, and a power conversion module that converts power supplied by the power supply module to generate power required for an operation of the electronic device 1.

At least one of the components of the electronic device 1 described above may be included in the display device according to the above-described embodiments. In addition, some of the individual modules functionally included within one module may be included within the display device, while others may be provided separately from the display device. For example, the display device includes the display module 11, and the processor 12, the memory 13 and the power module 14 may be provided in the form of other devices within the electronic device 1 other than the display device.

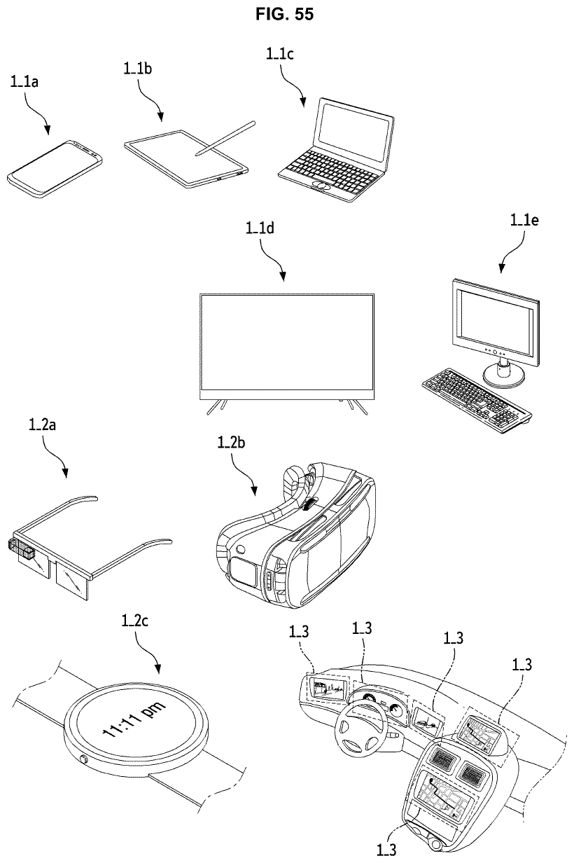

FIG. 55 illustrates schematic diagrams of electronic devices according to various embodiments.

Referring to FIG. 55, various electronic devices 1 to which the display device according to the embodiments is applied may include not only an image display electronic device such as a smart phone 1_1a, a tablet PC 1_1b, a laptop 1_1c, a TV 1_1d, and a desk monitor 1_1e, but also a wearable electronic device including a display module such as a smart glasses 1_2a, a head mounted display 1_2b, a smart watch 1_2c, and the like, and a vehicle electronic device 1_3 including a display module such as a Center Information Display (CID), a room mirror display, etc., located on a vehicle's instrument panel, center fascia, or dashboard.

In concluding the detailed description, those skilled in the art will appreciate that many variations and modifications can be made to the disclosed embodiments without departing from the spirit and scope of embodiments according to the present invention. Therefore, the disclosed embodiments of the invention are used in a generic and descriptive sense only and not for purposes of limitation.

What is claimed is:

1. A display device comprising:
a substrate including a display area and a non-display area;
a light emitting element layer on the substrate, overlapping the display area, and including a light emitting element;
a color filter layer on the light emitting element layer and overlapping the light emitting element layer;
an overcoat layer on the color filter layer;
a buffer layer directly on the overcoat layer; and
an optical member directly on the buffer layer,
wherein the buffer layer includes a first portion overlapping the optical member and a second portion that does not overlap the optical member and is outside the first portion,
the buffer layer includes a first surface facing the overcoat layer and a second surface opposite to the first surface, and
the second surface of the second portion of the buffer layer includes a curved surface.

2. The display device of claim 1, wherein the optical member includes an optical substrate on the buffer layer and an optical functional layer on the optical substrate, and
the optical substrate directly contacts the buffer layer.

3. The display device of claim 2, wherein the optical functional layer does not contact the buffer layer.

4. The display device of claim 2, wherein the second portion of the buffer layer contacts the outermost side surface of the optical substrate.

5. The display device of claim 2, further comprising an adhesive residual pattern between the optical substrate and the buffer layer,
wherein the buffer layer directly contacts the adhesive residual pattern.

6. The display device of claim 1, wherein the outermost edge of the buffer layer is positioned inward relative to the outermost side surface of the overcoat layer.

7. The display device of claim 1, wherein:
a surface curing rate of the first portion of the buffer layer and a surface curing rate of the second portion of the buffer layer are different from each other.

8. The display device of claim 7, wherein the surface curing rate of the first portion of the buffer layer is greater than the surface curing rate of the second portion of the buffer layer.

9. The display device of claim 1, wherein a Young's modulus of the buffer layer is in a range of 700 MPa to 800 MPa.

10. A display device comprising:
a substrate including a display area and a non-display area;
a light emitting element layer on the substrate, overlapping the display area, and including a light emitting element;
a color filter layer on the light emitting element layer and overlapping the light emitting element layer;
an overcoat layer on the color filter layer;
a buffer layer directly on the overcoat layer; and
an optical member directly on the buffer layer,
wherein the buffer layer includes a first portion overlapping the optical member and a second portion that does not overlap the optical member and is outside the first portion,
the buffer layer includes a first buffer layer directly on the overcoat layer and a second buffer layer between the first buffer layer and the optical member, and
a surface curing rate of the first portion of the second buffer layer and a surface curing rate of the second portion of the second buffer layer are different from each other.

11. The display device of claim 10, wherein the surface curing rate of the first portion of the second buffer layer is greater than the surface curing rate of the second portion of second the buffer layer.

12. The display device of claim 10, wherein a Young's modulus of the first buffer layer and a Young's modulus of the second buffer layer are different from each other.

13. The display device of claim 12, wherein the Young's modulus of the first buffer layer is greater than the Young's modulus of the second buffer layer.

14. The display device of claim 13, wherein the Young's modulus of the first buffer layer is 100 MPa or less, and the Young's modulus of the second buffer layer is in a range of 700 MPa to 800 MPa.

15. The display device of claim 14, wherein the optical member includes an optical substrate and an optical functional layer on the optical substrate, and
the optical substrate directly contacts the second buffer layer.

16. The display device of claim 15, wherein the optical functional layer does not contact the buffer layer.

17. The display device of claim 15, wherein the second portion of the second buffer layer contacts the outermost side surface of the optical substrate.

18. The display device of claim 15, further comprising an adhesive residual pattern between the optical substrate and the second buffer layer,
wherein the second buffer layer directly contacts the adhesive residual pattern.

19. The display device of claim 10, wherein the outermost edge of the buffer layer is positioned inward relative to the outermost side surface of the overcoat layer.

20. An electronic device comprising:
a display device for displaying an image; and
a processor for transmitting an image data signal for displaying the image to the display device,
wherein the display device comprises:
a substrate including a display area and a non-display area;
a light emitting element layer on the substrate, overlapping the display area, and including a light emitting element;
a color filter layer on the light emitting element layer and overlapping the light emitting element layer;
an overcoat layer on the color filter layer;
a buffer layer directly on the overcoat layer; and
an optical member directly on the buffer layer,
wherein the buffer layer includes a first portion overlapping the optical member and a second portion that does not overlap the optical member and is positioned outside the first portion, the buffer layer includes a first surface facing the overcoat layer and a second surface opposite to the first surface, and
the second surface of the second portion of the buffer layer includes a curved surface.
